(19) United States
(12) Patent Application Publication
(10) Pub. No.: US 2026/0314482 A1
(43) Pub. Date: Oct. 8, 2026

(54) SEMICONDUCTOR STRUCTURE AND METHOD FOR PRODUCING SAME

(71) Applicant: MITSUI CHEMICALS, INC., Chuo-ku, Tokyo (JP)

(72) Inventor: Yasuhisa KAYABA, Chuo-ku, Tokyo (JP)

(73) Assignee: MITSUI CHEMICALS, INC., Chuo-ku, Tokyo (JP)

(21) Appl. No.: 19/479,171

(22) PCT Filed: Apr. 22, 2024
(86) PCT No.: PCT/JP2024/015782

§ 371 Date: Oct. 27, 2025

(30) Foreign Application Priority Data
Apr. 28, 2023 (JP) 2023-075195

(51) Int. Cl. H10W 74/47; H10W 20/20; H10W 80/00; H10W 90/00

(52) U.S. Cl. CPC H10W 74/47; H10W 20/211; H10W 80/301; H10W 90/792

(57) ABSTRACT

A semiconductor structure, including: a composite substrate that comprises two-dimensionally arranged plural silicon dies and an organic gap fill material filled between the plural silicon dies; and a silicon die that is hybrid-bonded to at least one of the plural silicon dies of the composite substrate, either directly or via another layer.

### TECHNICAL FIELD

The present disclosure relates to a semiconductor structure and a method of producing the same.

### BACKGROUND ART

In recent years, from the standpoint of increasing the integration of semiconductor devices, studies have been conducted on technologies for stacking a semiconductor substrate and a semiconductor chip (e.g., silicon die) in the thickness direction.

For example, Patent Document 1 discloses a semiconductor structure including: a die set that is arranged on a wiring layer; and a silicon-containing inorganic gap fill material that is arranged on the wiring layer and surrounds the die set.

In the semiconductor structure of Patent Document 1, the wiring layer is arranged inside a substrate called an interposer (see claim 2 of Patent Document 1).

In contrast to the semiconductor structure of Patent Document 1, a technology is also known in which plural semiconductor chips (e.g., silicon dies) are stacked and bonded together using a solder, without the use of an interposer. This technology is known as EMIB (Embedded Multi-die Interconnect Bridge) (see, for example, Non-patent Document 1).
Patent Document 1: U.S. Patent Publication No. 2022/0013504
Non-patent Document 1: EE Times Japan, Process Technology, Akira Fukuda's Device News (109) Advanced Packaging Technologies Explained by TSMC (8), “Summary of Intel's High-Performance High-Density Packaging Technology ‘EMIB”, [online], ITmedia Inc., [searched on Jan. 13, 2023], internet <URL: https://eetimes.itmedia.co.jp/ee/articles/1705/10/news016.html>

### SUMMARY OF THE INVENTION

### Technical Problem

As a method of obtaining a semiconductor structure by stacking plural semiconductor chips (e.g., silicon dies), it is conceivable to employ a method of obtaining a semiconductor structure by preparing a composite substrate that includes two-dimensionally arranged plural silicon dies and a gap fill material filled between the plural silicon dies, and subsequently hybrid-bonding another silicon die, either directly or via another layer, to at least one of the plural silicon dies of the composite substrate.

The term “hybrid-bonding” used herein refers to a mode of bonding electrodes with each other and insulating films with each other by bringing into contact with two surfaces on which an insulating material and an electrode are exposed.

However, when an inorganic gap fill material is applied as the gap fill material in the above-described method of obtaining a semiconductor structure, a film stress of the inorganic gap fill material may cause warping of the resulting semiconductor structure.

The disclosure was made in view of the above-described problem.

An object of one aspect of the disclosure is to provide: a semiconductor structure in which warping is inhibited, the semiconductor structure including a structure in which a silicon die is hybrid-bonded, either directly or via another layer, to at least one of two-dimensionally arranged plural silicon dies of a composite substrate that includes the plural silicon dies and a gap fill material filled between the plural silicon dies; and a method of producing the same.

### Solution to Problem

Concrete means for solving the above-described problems encompass the following aspects.

<1> A semiconductor structure, comprising:
a composite substrate that comprises two-dimensionally arranged plural silicon dies and an organic gap fill material filled between the plural silicon dies; and
a silicon die that is hybrid-bonded to at least one of the plural silicon dies of the composite substrate, either directly or via another layer.

<2> The semiconductor structure according to <1>, comprising plural composite substrates,
wherein the plural silicon dies of two composite substrates that are adjacent to each other in a stacking direction among the plural composite substrates are hybrid-bonded either directly or via another layer.

<3> The semiconductor structure according to <2>, wherein, among the plural composite substrates, a composite substrate arranged as at least one of outermost layers comprises a through electrode.

<4> The semiconductor structure according to <2> or <3>, wherein the plural silicon dies of the two composite substrates that are adjacent to each other in the stacking direction each comprise, on at least a side of a surface to be hybrid-bonded, a silicon die bonding layer that comprises an insulating layer and an electrode.

<5> The semiconductor structure according to any one of <2> to <4>, wherein:
the plural silicon dies of the two composite substrates that are adjacent to each other in the stacking direction among the plural composite substrates are hybrid-bonded via a substrate-to-substrate bonding layer provided as the other layer, and
the substrate-to-substrate bonding layer comprises an insulating layer and an electrode.

<6> The semiconductor structure according to any one of <2> to <5>, comprising three or more of the composite substrates,
wherein:
among the three or more composite substrates, a composite substrate X that is a composite substrate other than two composite substrates constituting outermost layers comprises a through electrode, and
the plural silicon dies of a composite substrate adjacent to one surface of the composite substrate X and the plural silicon dies of a composite substrate adjacent to another surface of the composite substrate X are electrically connected via the through electrode in the composite substrate X.

<7> The semiconductor structure according to any one of <2> to <6>, further comprising a semiconductor substrate that comprises: a semiconductor substrate main body; a semiconductor substrate bonding layer that is arranged on the semiconductor substrate main body and comprises an insulating layer and an electrode; and a through electrode that penetrates through the semiconductor substrate main body,
wherein a semiconductor substrate bonding layer side of the semiconductor substrate is hybrid-bonded with the plural silicon dies of a composite substrate arranged as one of outermost layers among the plural composite substrates.

<8> The semiconductor structure according to any one of <1> to <8>, wherein an organic material constituting the organic gap fill material has a glass transition temperature of from 110° C. to 400° C.

<9> The semiconductor structure according to any one of <1> to <9>, wherein an organic material constituting the organic gap fill material comprises at least one selected from the group consisting of polyimides, polyamides, polyamideimides, maleimide resins, parylene, polyarylene ethers, polybenzoxazoles, benzocyclobutene resins, epoxy resins, and siloxane bond-containing resins.

<10> A method of producing a semiconductor structure, the method comprising the steps of:
preparing two composite substrates that are each temporarily fixed on a temporary fixing substrate and comprise two-dimensionally arranged plural silicon dies and an organic gap fill material filled between the plural silicon dies;
obtaining a laminated body X1 by hybrid-bonding, either directly or via another layer, the plural silicon dies of the two composite substrates that are each temporarily fixed on a temporary fixing substrate;
removing a temporary fixing substrate on one side of the laminated body X1 and thereby exposing a composite substrate on the one side to obtain a laminated body X2; and
removing a temporary fixing substrate on another side of the laminated body X2 to obtain a semiconductor structure.

<11> The method of producing a semiconductor structure according to <10>, satisfying at least one of the following:
in the step of preparing two composite substrates, at least one of the two composite substrates comprises a through electrode; or
after the step of preparing two composite substrates, a through electrode is formed in at least one of the two composite substrates.

<12> The method of producing a semiconductor structure according to <10> or <11>, further comprising, before the step of obtaining the laminated body X1, the step of forming a substrate-to-substrate bonding layer on at least one of the two composite substrates, the substrate-to-substrate bonding layer being in contact with the plural silicon dies of the at least one of the two composite substrates and comprising an insulating layer and an electrode,
wherein, in the step of obtaining the laminated body X1, the laminated body X1 is obtained by hybrid-bonding the plural silicon dies of the two composite substrates that are each temporarily fixed on a temporary fixing substrate, via the substrate-to-substrate bonding layer provided as the other layer.

<13> The method of producing a semiconductor structure according to any one of <10> to <12>, wherein a temperature of the hybrid-bonding is from 150° C. to 250° C.

<14> The method of producing a semiconductor structure according to any one of <10> to <13>, wherein an organic material constituting the organic gap fill material has a glass transition temperature of from 110° C. to 400° C.

<15> A method of producing a semiconductor structure, the method comprising the steps of:
preparing a semiconductor substrate comprising a semiconductor substrate main body, a semiconductor substrate bonding layer that is arranged on the semiconductor substrate main body and comprises an insulating layer and an electrode, and a through electrode;
preparing at least two composite substrates that are each temporarily fixed on a temporary fixing substrate and comprise two-dimensionally arranged plural silicon dies and an organic gap fill material filled between the plural silicon dies;
pasting a first composite substrate onto the semiconductor substrate bonding layer of the semiconductor substrate, hybrid-bonding the semiconductor substrate and the plural silicon dies of the first composite substrate, and then peeling off the temporary fixing substrate from the first composite substrate to expose the plural silicon dies; and
where n is defined as an integer of 1 or larger, performing operations of pasting and hybrid-bonding an (n+1)^{th} composite substrate onto an n^{th} composite substrate on the semiconductor substrate bonding layer of the semiconductor substrate either directly or via another layer, and then peeling off the temporary fixing substrate from the (n+1)^{th} composite substrate and thereby exposing the plural silicon dies, the operations being sequentially performed for integers from 1 to n to obtain a semiconductor structure.

<16> The method of producing a semiconductor structure according to <15>, wherein the organic gap fill material comprises at least one selected from the group consisting of polyimides, polyamides, polyamideimides, maleimide resins, parylene, polyarylene ethers, polybenzoxazoles, benzocyclobutene resins, epoxy resins, and siloxane bond-containing resins.

<17> The method of producing a semiconductor structure according to <15> or <16>, wherein at least one of a temperature of hybrid-bonding the semiconductor substrate and the plural silicon dies of the first composite substrate, or a temperature of pasting and hybrid-bonding the (n+1)^{th} composite substrate onto the n^{th} composite substrate either directly or via another layer, is from 150° C. to 250° C.

<18> The method of producing a semiconductor structure according to any one of <15> to <17>, satisfying at least one of the following:
in the step of preparing at least two composite substrates, at least one of the at least two composite substrates comprises a through electrode; or
after the step of preparing at least two composite substrates, a through electrode is formed in at least one of the at least two composite substrates.

<19> A method of producing a semiconductor structure, the method comprising the steps of:
preparing a semiconductor substrate comprising a semiconductor substrate main body, a semiconductor substrate bonding layer that is arranged on the semiconductor substrate main body and comprises an insulating layer and an electrode, and a through electrode;
two-dimensionally arranging and hybrid-bonding plural silicon dies on the semiconductor substrate bonding layer of the semiconductor substrate, and then filling gaps between the plural silicon dies with an organic gap fill material to form a first composite substrate; and
where n is defined as an integer of 1 or larger, performing operations of two-dimensionally arranging and hybrid-bonding plural silicon dies onto an n^{th} composite substrate on the semiconductor substrate bonding layer of the semiconductor substrate either directly or via another layer, and then filling gaps between the plural silicon dies with an organic gap fill material to form an (n+1)^{th} composite substrate, the operations being sequentially performed for integers from 1 to n to obtain a semiconductor structure.

<20> The method of producing a semiconductor structure according to <19>, satisfying at least one of the following:
the plural silicon dies for the formation of at least one of the first to the (n+1)^{th} composite substrates comprise a through electrode; or
a through electrode is formed in at least one of the first to the (n+1)^{th} composite substrates.

### Advantageous Effects of Invention

According to one aspect of the disclosure, the following are provided: a semiconductor structure in which warping is inhibited, the semiconductor structure including a structure in which a silicon die is hybrid-bonded, either directly or via another layer, to at least one of two-dimensionally arranged plural silicon dies of a composite substrate that includes the plural silicon dies and a gap fill material filled between the plural silicon dies; and a method of producing the same.

### BRIEF DESCRIPTION OF DRAWINGS

FIG. 1A is a schematic cross-sectional view illustrating a first specific example of the semiconductor structure of the disclosure.

FIG. 1B is a schematic cross-sectional view illustrating Modification Example 1 for the first specific example of the semiconductor structure of the disclosure.

FIG. 1C is a schematic cross-sectional view illustrating Modification Example 2 for the first specific example of the semiconductor structure of the disclosure.

FIG. 1D is a schematic cross-sectional view illustrating Modification Example 3 for the first specific example of the semiconductor structure of the disclosure.

FIG. 1E is a schematic cross-sectional view illustrating Modification Example 4 for the first specific example of the semiconductor structure of the disclosure.

FIG. 2 is a schematic cross-sectional view illustrating a second specific example of the semiconductor structure of the disclosure.

FIG. 3 is a schematic cross-sectional view illustrating a third specific example of the semiconductor structure of the disclosure.

FIG. 4 is a schematic cross-sectional view illustrating a fourth specific example of the semiconductor structure of the disclosure.

FIG. 5A is a schematic process diagram illustrating one example of the production method according to a first embodiment of the disclosure.

FIG. 5B is a schematic process diagram illustrating one example of the production method according to the first embodiment of the disclosure.

FIG. 5C is a schematic process diagram illustrating one example of the production method according to the first embodiment of the disclosure.

FIG. 5D is a schematic process diagram illustrating one example of the production method according to the first embodiment of the disclosure.

FIG. 5E is a schematic process diagram illustrating one example of the production method according to the first embodiment of the disclosure.

FIG. 5F is a schematic process diagram illustrating one example of the production method according to the first embodiment of the disclosure.

FIG. 5G is a schematic process diagram illustrating one example of the production method according to the first embodiment of the disclosure.

FIG. 5H is a schematic process diagram illustrating one example of the production method according to the first embodiment of the disclosure.

FIG. 6 is a schematic process diagram illustrating one example of the production method according to a second embodiment of the disclosure.

FIG. 7A is a schematic process diagram illustrating one example of the production method according to the second embodiment of the disclosure.

FIG. 7B is a schematic process diagram illustrating one example of the production method according to the second embodiment of the disclosure.

FIG. 8A is a schematic process diagram illustrating another example of the production method according to the second embodiment of the disclosure.

FIG. 8B is a schematic process diagram illustrating another example of the production method according to the second embodiment of the disclosure.

FIG. 9A is a schematic process diagram illustrating one example of the production method according to a third embodiment of the disclosure.

FIG. 9B is a schematic process diagram illustrating one example of the production method according to the third embodiment of the disclosure.

FIG. 9C is a schematic process diagram illustrating one example of the production method according to the third embodiment of the disclosure.

FIG. 9D is a schematic process diagram illustrating one example of the production method according to the third embodiment of the disclosure.

FIG. 9E is a schematic process diagram illustrating one example of the production method according to the third embodiment of the disclosure.

FIG. 9F is a schematic process diagram illustrating one example of the production method according to the third embodiment of the disclosure.

FIG. 9G is a schematic process diagram illustrating one example of the production method according to the third embodiment of the disclosure.

FIG. 10A is a schematic process diagram illustrating one example of the production method according to a fourth embodiment of the disclosure.

FIG. 10B is a schematic process diagram illustrating one example of the production method according to the fourth embodiment of the disclosure.

FIG. 10C is a schematic process diagram illustrating one example of the production method according to the fourth embodiment of the disclosure.

FIG. 10D is a schematic process diagram illustrating one example of the production method according to the fourth embodiment of the disclosure.

FIG. 10E is a schematic process diagram illustrating one example of the production method according to the fourth embodiment of the disclosure.

FIG. 10F is a schematic process diagram illustrating one example of the production method according to the fourth embodiment of the disclosure.

FIG. 10G is a schematic process diagram illustrating one example of the production method according to the fourth embodiment of the disclosure.

FIG. 10H is a schematic process diagram illustrating one example of the production method according to the fourth embodiment of the disclosure.

### DESCRIPTION OF EMBODIMENTS

In the disclosure, those numerical ranges that are expressed with “to” each denote a range that includes the numerical values stated before and after “to” as the lower limit value and the upper limit value, respectively.

In a set of numerical ranges that are stated in a stepwise manner in the disclosure, the upper limit value or the lower limit value of one numerical range may be replaced with the upper limit value or the lower limit value of other numerical range. Further, in a numerical range stated in the disclosure, the upper limit value or the lower limit value of the numerical range may be replaced with a relevant value indicated in any of Examples.

### [Semiconductor Structure]

The semiconductor structure of the disclosure is a semiconductor substrate including:
a composite substrate that includes two-dimensionally arranged plural silicon dies and an organic gap fill material filled between the plural silicon dies; and
a silicon die that is hybrid-bonded to at least one of the plural silicon dies of the composite substrate, either directly or via another layer.

The other layer may be, for example, a substrate-to-substrate bonding layer that includes an insulating layer and an electrode.

The semiconductor structure of the disclosure is a semiconductor structure including a structure in which a silicon die is hybrid-bonded, either directly or via another layer, to at least one of two-dimensionally arranged plural silicon dies of a composite substrate that includes the plural silicon dies and a gap fill material filled between the plural silicon dies. In the semiconductor structure of the disclosure, an organic gap fill material is applied as the gap fill material. By this, warping of the semiconductor structure is inhibited as compared to a case of using an inorganic gap fill material.

Further, in the semiconductor structure of the disclosure, another silicon die is hybrid-bonded to at least one of the plural silicon dies of the composite substrate, either directly or via another layer.

In other words, the semiconductor structure of the disclosure includes a structure in which plural silicon dies are stacked and hybrid-bonded either directly or via another layers.

By this, malfunction and poor reliability are inhibited as compared to a semiconductor structure that includes a structure in which plural silicon dies are stacked and solder-bonded.

The term “hybrid-bonding” used herein refers to a mode of bonding electrodes with each other and insulating films with each other by bringing into contact with two surfaces on which an insulating material and an electrode are exposed.

In the disclosure, the temperature of hybrid-bonding is preferably from 150° C. to 250° C.

It is noted here that the temperature of hybrid-bonding refers to the temperature of the bonding surfaces of two members to be hybrid-bonded.

In the semiconductor structure of the disclosure, two silicon dies that are adjacent to each other in a stacking direction (specifically, one of the plural silicon dies of the composite substrate, and a silicon die to be stacked and hybrid-bonded thereon either directly or via another layer) may each include, on at least a side of a surface to be hybrid-bonded, a silicon die bonding layer that includes an insulating layer and an electrode.

This allows the two silicon dies that are adjacent to each other in the stacking direction to be more effectively hybrid-bonded.

The semiconductor structure of the disclosure may include plural composite substrates.

In the semiconductor structure of the disclosure that includes plural composite substrates (hereinafter, also referred to as “semiconductor structure A”), plural silicon dies of two composite substrates that are adjacent to each other in the stacking direction among the plural composite substrates are hybrid-bonded either directly or via another layer. The hybrid-bonding in this semiconductor structure A is also included in the above-described concept that “another silicon die is hybrid-bonded to at least one of the plural silicon dies of the composite substrate, either directly or via another layer”. In this case, the another silicon die is an element in another composite substrate.

The semiconductor structure A (i.e., the semiconductor structure of the disclosure that includes plural composite substrates) is, in other words, as follows.

The semiconductor structure A is a semiconductor structure including plural composite substrates that are stacked either directly or via another layers, in which,
the plural composite substrates each include two-dimensionally arranged plural silicon dies and an organic gap fill material filled between the plural silicon dies,
the plural silicon dies of two composite substrates that are adjacent to each other in the stacking direction among the plural composite substrates are hybrid-bonded either directly or via another layer, and
in a composite substrate arranged as at least one of outermost layers among the plural composite substrates, the plural silicon dies include a through electrode.

The composite substrate in the semiconductor structure of the disclosure may include a through electrode.

The “through electrode” that may be included in the composite substrate refers to an electrode that penetrates through a silicon die or organic gap fill material in the composite substrate.

In the semiconductor structure A (i.e., the semiconductor structure of the disclosure that includes plural composite substrates), at least one of the plural composite substrates (e.g., a composite substrate arranged as at least one of outermost layers) may include a through electrode.

In the semiconductor structure of the disclosure, a silicon die of the composite substrate and another silicon die hybrid-bonded thereto either directly or via another layer may each include, on at least a side of a surface to be hybrid-bonded, a silicon die bonding layer that includes an insulating layer and an electrode.

In the semiconductor structure A (i.e., the semiconductor structure of the disclosure that includes plural composite substrates), the plural silicon dies of two composite substrates that are adjacent to each other in the stacking direction may each include, on at least a side of a surface to be hybrid-bonded, a silicon die bonding layer that includes an insulating layer and an electrode.

In the semiconductor structure of the disclosure, a silicon die of the composite substrate and another silicon die hybrid-bonded thereto either directly or via another layer may be hybrid-bonded via a substrate-to-substrate bonding layer that is provided as the other layer and includes an insulating layer and an electrode.

In the semiconductor structure A (i.e., the semiconductor structure of the disclosure that includes plural composite substrates), the plural silicon dies of two composite substrates that are adjacent to each other in the stacking direction may be hybrid-bonded via a substrate-to-substrate bonding layer that is provided as other layer and includes an insulating layer and an electrode.

In the semiconductor structure of the disclosure (specifically, the semiconductor structure A):
three or more composite substrates may be provided;
among the three or more composite substrates, a composite substrate X that is a composite substrate other than two composite substrates constituting outermost layers may include a through electrode; and
the plural silicon dies of the composite substrate adjacent to one of the surfaces of the composite substrate X and the plural silicon dies of the composite substrate adjacent to the another surface of the composite substrate X may be electrically connected via the through electrode in the composite substrate X.

The semiconductor structure of the disclosure may further include a semiconductor substrate that includes: a semiconductor substrate main body; a semiconductor substrate bonding layer that is arranged on the semiconductor substrate main body and includes an insulating layer and an electrode; and a through electrode that penetrates through the semiconductor substrate main body, and
a semiconductor substrate bonding layer side of the semiconductor substrate may be hybrid-bonded with the plural silicon dies of a composite substrate.

The semiconductor structure A (i.e., the semiconductor structure of the disclosure that includes plural composite substrates) may further include a semiconductor substrate that includes: a semiconductor substrate main body; a semiconductor substrate bonding layer that is arranged on the semiconductor substrate main body and includes an insulating layer and an electrode; and a through electrode that penetrates through the semiconductor substrate main body, and
a semiconductor substrate bonding layer side of the semiconductor substrate may be hybrid-bonded with the plural silicon dies of a composite substrate arranged as one of outermost layers among the plural composite substrates.

### <Specific Examples of Semiconductor Structure>

First, specific examples of the semiconductor structure of the disclosure will be described referring to the drawings.

It is noted here, however, that the semiconductor structure of the disclosure is not limited to the below-described specific examples.

In the following description, substantially the same elements (e.g., components or parts) are assigned with the same symbol, and redundant description thereof may be omitted.

### First Specific Example

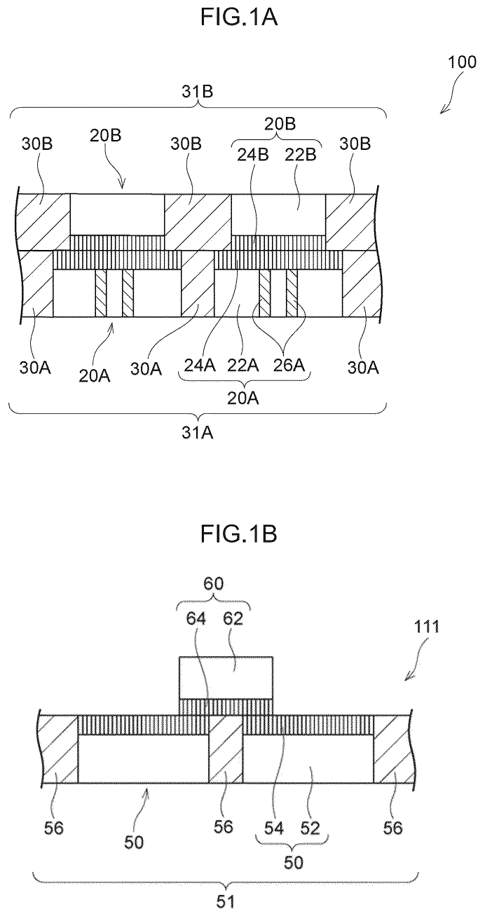

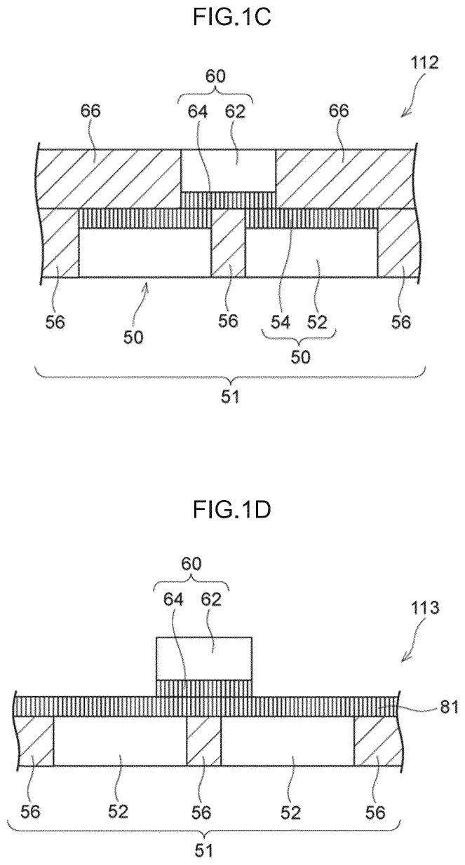

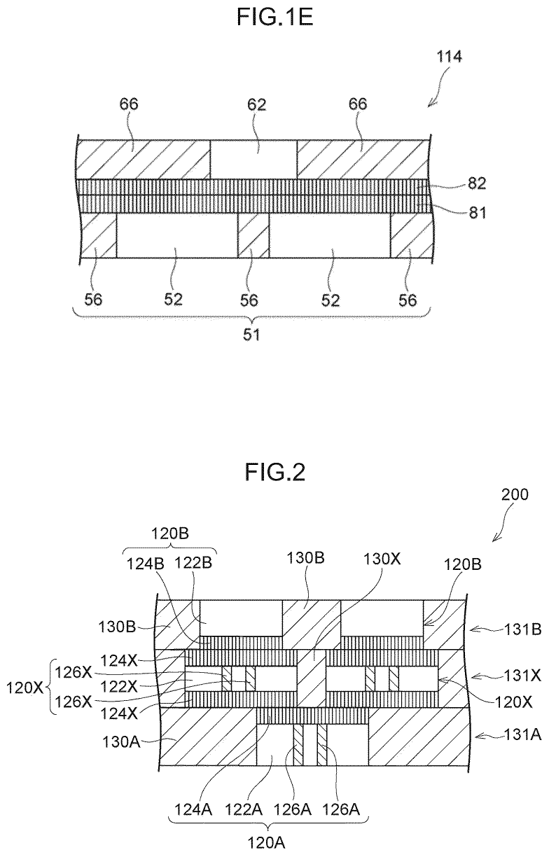

FIG. 1A is a schematic cross-sectional view illustrating a semiconductor structure 100 that is a first specific example of the semiconductor structure of the disclosure.

Particularly, the semiconductor structure 100 is a specific example of the semiconductor structure A (i.e., the semiconductor structure of the disclosure that includes plural composite substrates).

As illustrated in FIG. 1A, the semiconductor structure 100 includes a composite substrate 31A and a composite substrate 31B as two composite substrates that are adjacent to each other in the stacking direction.

The composite substrate 31A includes two-dimensionally arranged plural silicon dies 20A, and an organic gap fill material 30A filled between the plural silicon dies 20A. The plural silicon dies 20A each include a silicon die main body 22A, and further include a silicon die bonding layer 24A, which includes an insulating layer (not illustrated) and an electrode (not illustrated), on at least a side of a surface to be hybrid-bonded.

The composite substrate 31A includes through electrodes 26A.

The through electrodes 26A penetrate through at least the silicon die main body 22A in the thickness direction.

The composite substrate 31B in the semiconductor structure 100 is electrically connected to an external circuit board or the like via the through electrodes 26A.

Similarly, the composite substrate 31B includes two-dimensionally arranged plural silicon dies 20B, and an organic gap fill material 30B filled between the plural silicon dies 20B. The plural silicon dies 20B each include a silicon die main body 22B, and further include a silicon die bonding layer 24B, which includes an insulating layer (not illustrated) and an electrode (not illustrated), on at least a side of a surface to be hybrid-bonded.

In the semiconductor structure 100, the plural silicon dies 20A of the composite substrate 31A and the plural silicon dies 20B of the composite substrate 31B are hybrid-bonded.

More specifically, in the semiconductor structure 100, the silicon die bonding layers 24A of the plural silicon dies 20A and the silicon die bonding layers 24B of the plural silicon dies 20B are hybrid-bonded.

In the semiconductor structure 100, two silicon dies 20A and two silicon dies 20B are hybrid-bonded in one-to-one correspondence; however, the mode of hybrid-bonding is not limited to this.

For example, a single silicon die may be hybrid-bonded with two silicon dies (see, for example, FIGS. 1B to 1D and FIG. 2 below).

In short, it is sufficient that at least one of plural silicon dies of a certain composite substrate is hybrid-bonded with at least one of plural silicon dies of another composite substrate adjacent to the certain composite substrate in a stacking method.

This also applies to the below-described other specific examples.

The semiconductor structure 100 may include composite substrates other than the two composite substrates 31A and 31B as composite substrates to be stacked.

The number of composite substrates to be stacked is preferably from 2 to 30, more preferably from 2 to 20.

Further, the semiconductor structure 100 may include layers other than the composite substrates (e.g., the below-described substrate-to-substrate bonding layer).

For example, in the semiconductor structure 100, plural silicon dies of two of the plural composite substrates that are adjacent to each other in the stacking direction (i.e., the plural silicon dies 20A and the plural silicon dies 20B) may be hybrid-bonded via a substrate-to-substrate bonding layer provided as other layer.

Thus far, the semiconductor structure 100, which is a specific example of the semiconductor structure A (i.e., the semiconductor structure of the disclosure that includes plural composite substrates), has been described; however, the semiconductor structure of the disclosure is not limited to the semiconductor structure A.

The semiconductor structure of the disclosure is sufficient as long as it includes a composite substrate, and a silicon die that is hybrid-bonded to at least one of plural silicon dies of the composite substrate either directly or via another layer.

Modification Examples 1 to 4 of the semiconductor structure 100 will now be described.

Modification Examples 1 to 4 are specific examples of the semiconductor structure of the present disclosure other than the semiconductor structure A (i.e., the semiconductor structure of the disclosure that includes plural composite substrates).

### Modification Example 1 of First Specific Example

FIG. 1B is a schematic cross-sectional view of a semiconductor structure 111 that is Modification Example 1 of the first specific example of the semiconductor structure of the disclosure.

As illustrated in FIG. 1B, the semiconductor structure 111 includes a composite substrate 51 and a silicon die 60.

The composite substrate 51 includes two-dimensionally arranged plural silicon dies 50, and an organic gap fill material 56 filled between the plural silicon dies 50.

The silicon die 60 is hybrid-bonded directly to two silicon dies 50 of the composite substrate 51.

The silicon dies 50 each include a silicon die main body 52, and further include a silicon die bonding layer 54, which includes an insulating layer (not illustrated) and an electrode (not illustrated), on a side of a surface to be hybrid-bonded.

The silicon die 60 includes a silicon die main body 62, and further includes a silicon die bonding layer 64, which includes an insulating layer (not illustrated) and an electrode (not illustrated), on a side of a surface to be hybrid-bonded.

In the semiconductor structure 111, the silicon die 60 or the composite substrate 51 (specifically, the silicon die 60 or the organic gap fill material 56) may include a through electrode.

### Modification Example 2 of First Specific Example

FIG. 1C is a schematic cross-sectional view of a semiconductor structure 112 that is Modification Example 2 of the first specific example of the semiconductor structure of the disclosure.

In the semiconductor structure 112, an organic gap fill material 66 is formed around the silicon die 60 of the semiconductor structure 111. Except for this point, the configuration of the semiconductor structure 112 is the same as the configuration of the semiconductor structure 111.

### Modification Example 3 of First Specific Example

FIG. 1D is a schematic cross-sectional view of a semiconductor structure 113 that is Modification Example 3 of the first specific example of the semiconductor structure of the disclosure.

In the semiconductor structure 113, the silicon die bonding layer 54 of the semiconductor structure 111 is omitted and, instead, a substrate-to-substrate bonding layer 81 which includes an insulating layer (not illustrated) and an electrode (not illustrated) is formed on the composite substrate 51 (i.e., over the silicon die main bodies 52 and the organic gap fill material 56), and the silicon die 60 is hybrid-bonded onto the substrate-to-substrate bonding layer 81.

Except for this point, the configuration of the semiconductor structure 113 is the same as the configuration of the semiconductor structure 111.

### Modification Example 4 of First Specific Example

FIG. 1E is a schematic cross-sectional view of a semiconductor structure 104 that is Modification Example 4 of the first specific example of the semiconductor structure of the disclosure.

In the semiconductor structure 104, the silicon die bonding layer 54 and the silicon die bonding layer 64 of the semiconductor structure 111 are omitted and, instead, the substrate-to-substrate bonding layer 81 which includes an insulating layer (not illustrated) and an electrode (not illustrated) is formed on the composite substrate 51 (i.e., over the silicon die main bodies 52 and the organic gap fill material 56); a substrate-to-substrate bonding layer 82 is formed over the silicon die main body 62 and the organic gap fill material 66; and the substrate-to-substrate bonding layer 81 and the substrate-to-substrate bonding layer 82 are hybrid-bonded, whereby the semiconductor structure 104 is formed.

Except for this point, the configuration of the semiconductor structure 104 is the same as the configuration of the semiconductor structure 111.

### Second Specific Example

FIG. 2 is a schematic cross-sectional view illustrating a semiconductor structure 200 that is a second specific example of the semiconductor structure of the disclosure.

Particularly, the semiconductor structure 200 is a specific example of the semiconductor structure A (i.e., the semiconductor structure of the disclosure that includes plural composite substrates).

As illustrated in FIG. 2, the semiconductor structure 200 includes, as composite substrates (i.e., composite substrates each including two-dimensionally arranged plural silicon dies and an organic gap fill material filled between the plural silicon dies):
composite substrates 131A and 131B, which are two outermost layers; and
a composite substrate 131X, which is the composite substrate X (i.e., the composite substrate X that is a composite substrate other than the two outermost layers) serving as an intermediate layer.

The composite substrate 131A includes two-dimensionally arranged plural silicon dies 120A, and an organic gap fill material 130A filled between the plural silicon dies 120A.

The plural silicon dies 120A each include a silicon die main body 122A, and further include a silicon die bonding layer 124A, which includes an insulating layer (not illustrated) and an electrode (not illustrated), on at least one surface to be hybrid-bonded.

The composite substrate 131A includes through electrodes 126A.

The through electrodes 126A penetrate through at least the silicon die main body 22A in the thickness direction.

The semiconductor structure 200 is electrically connected to an external circuit board or the like via the through electrodes 126A.

The composite substrate 131B includes two-dimensionally arranged plural silicon dies 120B, and an organic gap fill material 130B filled between the plural silicon dies 120B.

The plural silicon dies 120B each include a silicon die main body 122B, and further include a silicon die bonding layer 124B, which includes an insulating layer (not illustrated) and an electrode (not illustrated), on at least one surface to be hybrid-bonded.

The composite substrate 131X includes two-dimensionally arranged plural silicon dies 120X, and an organic gap fill material 130X filled between the plural silicon dies 120X.

The plural silicon dies 120X each include a silicon die main body 122X, and further include silicon die bonding layers 124X, each of which includes an insulating layer (not illustrated) and an electrode (not illustrated), on both surfaces to be hybrid-bonded.

The composite substrate 131X includes through electrodes 126X.

The through electrodes 126X penetrate through at least the silicon die main body 122X in the thickness direction.

In the semiconductor structure 200, the plural silicon dies 120A of the composite substrate 131A and the plural silicon dies 120X of the composite substrate 131X are hybrid-bonded in those parts of the silicon die bonding layers 124A of the plural silicon dies 120A and the silicon die bonding layers 124X of the plural silicon dies 120X.

Further, in the semiconductor structure 200, the plural silicon dies 120B of the composite substrate 131B and the plural silicon dies 120X of the composite substrate 131X are hybrid-bonded in those parts of the silicon die bonding layers 124B of the plural silicon dies 120B and the silicon die bonding layers 124X of the plural silicon dies 120X.

Moreover, in the semiconductor structure 200, the silicon dies 120A of the composite substrate 131A and the silicon dies 120B of the composite substrate 131B (i.e., the silicon dies of the composite substrates that are not hybrid-bonded) are electrically connected via the through electrodes 126X and the silicon die bonding layers 124X on both sides in the composite substrate 131X.

In the semiconductor structure 200, there is only one composite substrate X serving as an intermediate layer (single layer); however, there may be two or more composite substrates X serving as intermediate layers (two or more layers).

The number of composite substrates to be stacked in the semiconductor structure 200 is preferably from 3 to 30, more preferably from 3 to 20.

The semiconductor structure 200 may also include layers other than the composite substrates (e.g., the below-described substrate-to-substrate bonding layer).

For example, in the semiconductor structure 200, plural silicon dies of two of the plural composite substrates that are adjacent to each other in the stacking direction may be hybrid-bonded via a substrate-to-substrate bonding layer provided as other layer.

When the semiconductor structure includes a substrate-to-substrate bonding layer, at least one of the silicon die bonding layers in the silicon dies may be omitted.

### Third Specific Example

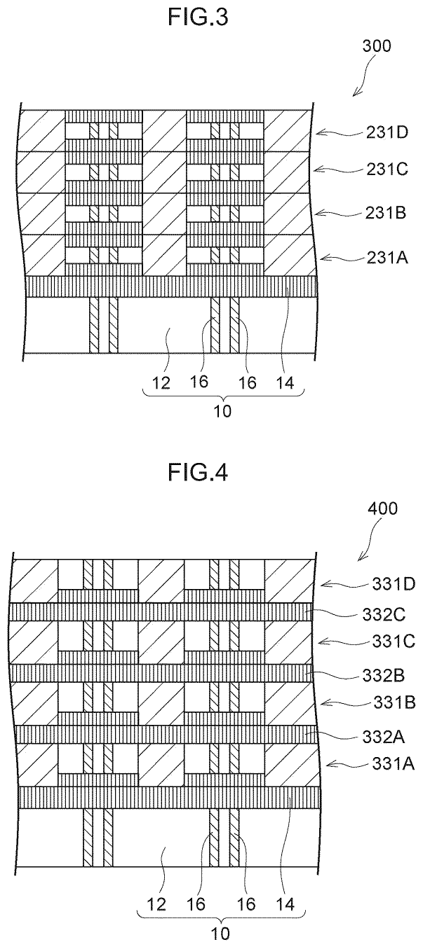

FIG. 3 is a schematic cross-sectional view illustrating a semiconductor structure 300 that is a third specific example of the semiconductor structure of the disclosure.

Particularly, the semiconductor structure 300 is a specific example of the semiconductor structure A (i.e., the semiconductor structure of the disclosure that includes plural composite substrates).

As illustrated in FIG. 3, the semiconductor substrate 300 is common with the above-described semiconductor structures 100 and 200 in that composite substrates each including two-dimensionally arranged plural silicon dies and an organic gap fill material filled between the plural silicon dies are stacked either directly or via another layer.

In the semiconductor structure 300, the composite substrates are composite substrates 231A to 231D.

The configuration of each of the composite substrates 231A to 231D is the same as the configuration of the composite substrate 131X in the semiconductor structure 200.

In other words, the composite substrates 231A to 231D each include two-dimensionally arranged plural silicon dies, and an organic gap fill material filled between the plural silicon dies.

The plural silicon dies in each of the composite substrates 231A to 231D each include:
a silicon die main body;
silicon die bonding layers that are arranged on both sides of the silicon die main body and each include an insulating layer (not illustrated) and an electrode (not illustrated); and
through electrodes that penetrate through the silicon die main body in the thickness direction.

The semiconductor structure 300 is different from the above-described semiconductor structures 100 and 200 in that it includes a semiconductor substrate 10.

In the semiconductor structure 300, the semiconductor substrate 10 includes: a semiconductor substrate main body 12; a semiconductor substrate bonding layer 14, which is arranged on the semiconductor substrate main body 12 and includes an insulating layer and an electrode; and through electrodes 16, which penetrate through the semiconductor substrate main body 12.

The through electrodes 16 penetrate through at least the semiconductor substrate main body 12 in the thickness direction.

The semiconductor structure 300 is electrically connected to an external circuit board or the like via the through electrodes 16.

In the semiconductor structure 300, the semiconductor substrate bonding layer 14 side of the semiconductor substrate 10 is hybrid-bonded with the plural silicon dies of the composite substrate 231A arranged as one of outermost layers.

Further, in the semiconductor structure 300:
the plural silicon dies of the composite substrate 231A are hybrid-bonded with the plural silicon dies of the composite substrate 231B;
the plural silicon dies of the composite substrate 231B are hybrid-bonded with the plural silicon dies of the composite substrate 231C; and
the plural silicon dies of the composite substrate 231C are hybrid-bonded with the plural silicon dies of the composite substrate 231D.

Moreover, in the semiconductor structure 300, via the through electrodes 16 of the semiconductor substrate 10 and the through electrodes of each silicon die in each composite substrate, an electrical connection between composite substrates that are not hybrid-bonded (e.g., an electrical connection between the composite substrate 231A and the composite substrate 231C) or an electrical connection between the semiconductor substrate and a composite substrate (e.g., the composite substrate 231C) that are not hybrid-bonded is realized as well.

The number of composite substrates to be stacked in the semiconductor structure 300 is preferably from 2 to 30, more preferably from 2 to 20.

### Fourth Specific Example

FIG. 4 is a schematic cross-sectional view illustrating a semiconductor structure 400 that is a fourth specific example of the semiconductor structure of the disclosure.

Particularly, the semiconductor structure 400 is a specific example of the semiconductor structure A (i.e., the semiconductor structure of the disclosure that includes plural composite substrates).

As illustrated in FIG. 4, the configuration of the semiconductor substrate 400 is the same as that of the semiconductor structure 300, except that substrate-to-substrate bonding layers 332A to 332C are arranged between the composite substrates, and that the silicon die bonding layers in the silicon dies are arranged only on one side of the respective silicon die main bodies.

In the semiconductor structure 400, the semiconductor substrate bonding layer 14 side of the semiconductor substrate 10 is hybrid-bonded with the plural silicon dies of the composite substrate 331A arranged as one of outermost layers.

Further, in the semiconductor structure 400:
the plural silicon dies of the composite substrate 331A are hybrid-bonded with the plural silicon dies of the composite substrate 331B via the substrate-to-substrate bonding layer 332A;
the plural silicon dies of the composite substrate 331B are hybrid-bonded with the plural silicon dies of the composite substrate 331C via the substrate-to-substrate bonding layer 332B; and
the plural silicon dies of the composite substrate 331C are hybrid-bonded with the plural silicon dies of the composite substrate 331D via the substrate-to-substrate bonding layer 332C.

Moreover, in the semiconductor structure 400, via the through electrodes 16 of the semiconductor substrate 10 and the through electrodes of each silicon die in each composite substrate, an electrical connection between composite substrates that are not hybrid-bonded (e.g., an electrical connection between the composite substrate 331A and the composite substrate 331C) or an electrical connection between the semiconductor substrate and a composite substrate (e.g., the composite substrate 331C) that are not hybrid-bonded is realized as well.

The number of composite substrates to be stacked in the semiconductor structure 400 is preferably from 2 to 30, more preferably from 2 to 20.

### [Embodiments of Method of Producing Semiconductor Structure]

A production method for producing the above-described semiconductor structure of the disclosure is not particularly limited, and examples thereof include the production methods according to the following embodiments.

### First Embodiment

The production method according to the first embodiment includes the steps of:
preparing two composite substrates that are each temporarily fixed on a temporary fixing substrate and include two-dimensionally arranged plural silicon dies and an organic gap fill material filled between the plural silicon dies;
obtaining a laminated body X1 by hybrid-bonding, either directly or via another layer, the plural silicon dies of the two composite substrates that are each temporarily fixed on a temporary fixing substrate;
removing the temporary fixing substrate on one side of the laminated body X1 and thereby exposing the composite substrate on the one side to obtain a laminated body X2; and
removing the temporary fixing substrate on the another side of the laminated body X2 to obtain a semiconductor structure.

If necessary, the production method according to the first embodiment may also include other steps.

The production method according to the first embodiment preferably satisfies at least one of the following:
in the step of preparing two composite substrates, at least one of the two composite substrates includes a through electrode; or
after the step of preparing two composite substrates, a through electrode is formed in at least one of the two composite substrates.

In other words, in a preferred embodiment, a through electrode may be formed in advance in the composite substrates to be prepared, or may be formed during the process of producing a semiconductor structure.

In the step of obtaining the laminated body X1, the temperature of the hybrid-bonding is preferably from 150° C. to 250° C.

By the production method according to the first embodiment, for example, the semiconductor structure 100 that is the first specific example described above can be produced.

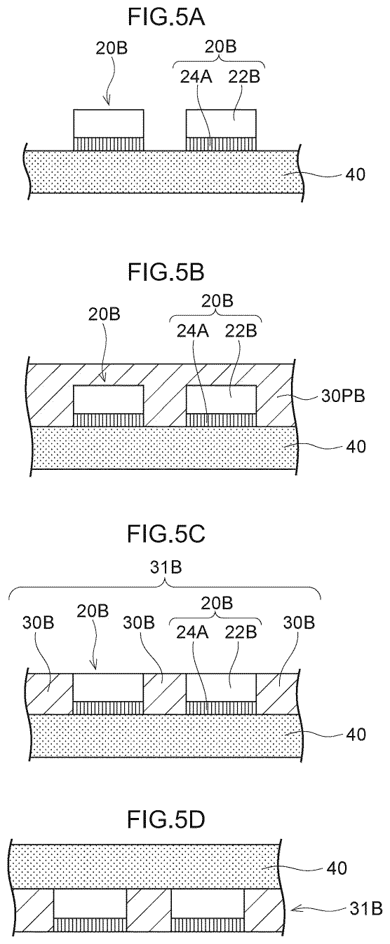

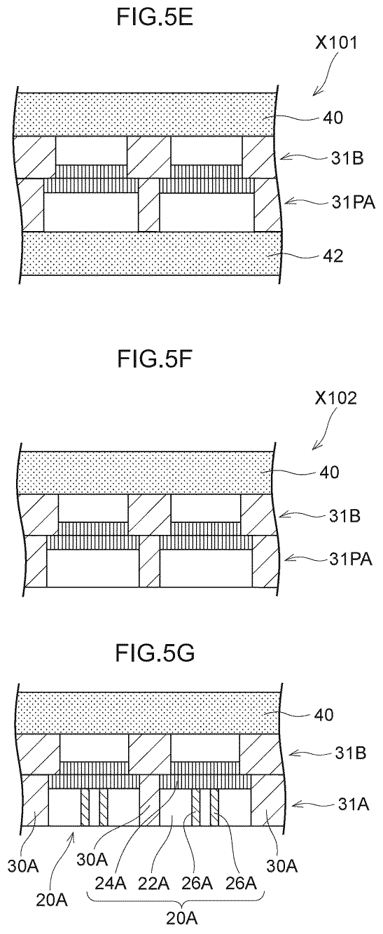

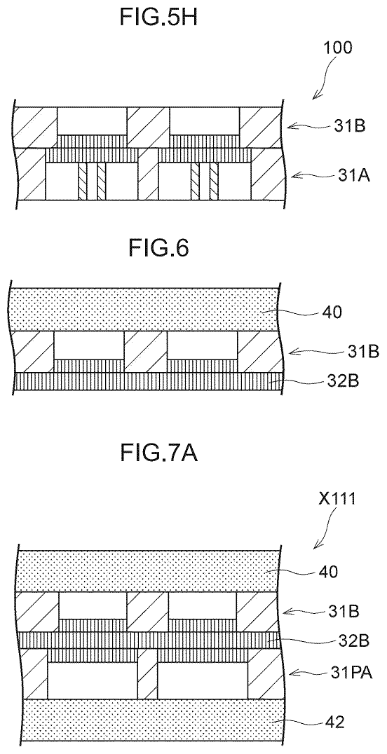

FIGS. 5A to 5H are schematic process diagrams illustrating one example of the production method according to the first embodiment for producing the semiconductor structure 100 that is the first specific example described above.

FIGS. 5A to 5C illustrate the step of preparing two composite substrates that are each temporarily fixed on a temporary fixing substrate and include two-dimensionally arranged plural silicon dies and an organic gap fill material filled between the plural silicon dies. First, as illustrated in FIG. 5A, plural silicon dies 20B are two-dimensionally arranged and temporarily fixed on a temporary fixing substrate 40.

Next, as illustrated in FIG. 5B, on the temporary fixing substrate 40 on which the plural silicon dies 20B have been temporarily fixed, an organic gap fill material layer 30PB is formed such that it fills gaps between the plural silicon dies 20B and covers the plural silicon dies 20B and the temporary fixing substrate 40.

Subsequently, as illustrated in FIG. 5C, the organic gap fill material layer 30PB is polished to expose the surfaces of the plural silicon dies 20B, leaving an organic gap fill material 30B between the plural silicon dies 20B.

As a result, a composite substrate 31B, which includes the plural silicon dies 20B that are temporarily fixed and two-dimensionally arranged on the temporary fixing substrate 40, and the organic gap fill material 30B filled between the plural silicon dies 20B, is obtained (FIG. 5C).

Further, in the same manner as the above-described process of obtaining the composite substrate 31B, a composite substrate 31PA, which includes plural silicon dies that are temporarily fixed and two-dimensionally arranged on a temporary fixing substrate, and an organic gap fill material filled between the plural silicon dies, is obtained (see FIG. 5E described below). It is noted here that the composite substrate 31PA is a precursor of a composite substrate 31A. The composite substrate 31A is obtained by forming through electrodes 26A in the composite substrate 31PA.

The composite substrate 31B and the composite substrate 31PA do not need to have exactly the same configuration.

For example, the size of the silicon dies may be different between the composite substrate 31B and the composite substrate 31PA as in this example, or may be the same.

FIGS. 5D and 5E illustrate the step of obtaining a laminated body X1 by hybrid-bonding, either directly or via another layer, the plural silicon dies of the two composite substrates that are each temporarily fixed on a temporary fixing substrate. FIG. 5D is obtained by inverting FIG. 5C.

As illustrated in FIG. 5E, in this example, the composite substrate 31B temporarily fixed on the temporary fixing substrate 40 and the composite substrate 31PA temporarily fixed on a temporary fixing substrate 42 are pasted together, and the plural silicon dies of the composite substrate 31B and the plural silicon dies of the composite substrate 31PA are hybrid-bonded to obtain a laminated body X101 as the laminated body X1.

In each embodiment, when composite substrates are pasted together, if necessary, the surfaces of the composite substrates to be pasted together may be cleaned (e.g., polished and/or plasma-treated) before being pasted together.

FIG. 5F illustrates one example of the step of removing the temporary fixing substrate on one side of the laminated body X1 and thereby exposing the composite substrate on the one side to obtain a laminated body X2.

As illustrated in FIG. 5F, in this example, the temporary fixing substrate 42 on one side of the laminated body X101 is removed to expose the composite substrate 31PA on one side, whereby a laminated body X102 is obtained as the laminated body X2.

FIG. 5G illustrates the step of forming through electrodes in the plural silicon dies of the exposed composite substrate in the laminated body X2.

As illustrated in FIG. 5G, in this example, the through electrodes 26A are formed in the plural silicon dies of the exposed composite substrate 31PA in the laminated body X102. As a result, the composite substrate 31A is obtained.

FIG. 5H illustrates the step of, after the formation of the through electrodes, removing the temporary fixing substrate on the another side of the laminated body X2 to obtain a semiconductor structure.

As illustrated in FIG. 5H, in this example, the temporary fixing substrate 40 on the another side of the laminated body X102 obtained as the laminated body X2 is removed, whereby the semiconductor structure 100 that is the first specific example described above is obtained.

### Second Embodiment

The production method according to the second embodiment is the production method according to the first embodiment that further includes, before the step of obtaining the laminated body X1, the step of forming a substrate-to-substrate bonding layer on at least one of the two composite substrates, the substrate-to-substrate bonding layer being in contact with the plural silicon dies of the at least one of the two composite substrates and includes an insulating layer and an electrode, and
in the step of obtaining the laminated body X1, the laminated body X1 is obtained by hybrid-bonding the plural silicon dies of the two composite substrates that are temporarily fixed on the respective temporary fixing substrates, via the substrate-to-substrate bonding layer provided as the above-described other layer.

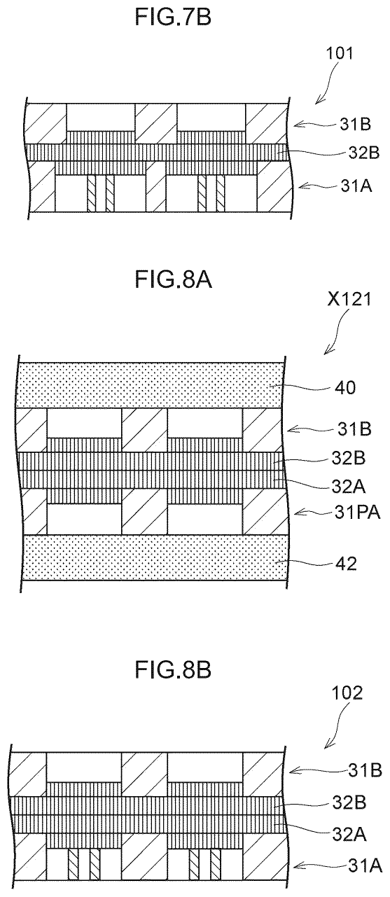

By the production method according to the second embodiment, for example, a semiconductor structure 101 having a structure in which a substrate-to-substrate bonding layer is added between two composite substrates in the semiconductor structure 100 that is the first specific example described above can be produced (see FIG. 7B).

FIGS. 6, 7A, and 7B are schematic process diagrams illustrating one example of the production method according to the second embodiment for producing the semiconductor structure 101.

As illustrated in FIG. 6, in this example, before the step of obtaining the laminated body X1, a substrate-to-substrate bonding layer 32B, which is in contact with the plural silicon dies of the composite substrate 31B and includes an insulating layer and an electrode, is formed on the composite substrate 31B, which is one of two composite substrates.

Subsequently, the composite substrate 31B on which the substrate-to-substrate bonding layer 32B has been formed is pasted together with the composite substrate 31PA, and the composite substrate 31B temporarily fixed on the temporary fixing substrate 40 and the composite substrate 31PA temporarily fixed on the temporary fixing substrate 42 are hybrid-bonded via the substrate-to-substrate bonding layer 32B to obtain a laminated body X111 as the laminated body X1 (see FIG. 7A).

Thereafter, in the same manner as in the production method according to the first embodiment, the temporary fixing substrate 40 is removed, through electrodes are formed in the silicon dies of the composite substrate 31PA, and the temporary fixing substrate 42 is removed, whereby the semiconductor structure 101, which has a structure in which the substrate-to-substrate bonding layer 32B is added between the two composite substrates in the semiconductor structure 100, is obtained (see FIG. 7B).

### Modification Example of Second Embodiment

In the production method according to the second embodiment, a semiconductor structure 102 in which two or more substrate-to-substrate bonding layers are arranged between two composite substrates can be obtained as well (see FIG. 8B).

In this case, before the step of obtaining the laminated body X1, not only the substrate-to-substrate bonding layer 32B, which is in contact with the plural silicon dies of the composite substrate 31B and includes an insulating layer and an electrode, is formed on the composite substrate 31B that is one of the two composite substrates, but also a substrate-to-substrate bonding layer 32A, which is in contact with the plural silicon dies of the composite substrate 31PA and includes an insulating layer and an electrode, is formed on the composite substrate 31PA that is the other of the two composite substrates.

Subsequently, the two composite substrates are pasted together in an arrangement in which the substrate-to-substrate bonding layer 32B and the substrate-to-substrate bonding layer 32A are in contact with each other, and the composite substrate 31B temporarily fixed on the temporary fixing substrate 40 and the composite substrate 31PA temporarily fixed on the temporary fixing substrate 42 are hybrid-bonded via the substrate-to-substrate bonding layer 32A and the substrate-to-substrate bonding layer 32B to obtain a laminated body X121 as the laminated body X1 (see FIG. 8A).

Thereafter, in the same manner as in the production method according to the first embodiment, the temporary fixing substrate 40 is removed, through electrodes are formed in the silicon dies of the composite substrate 31PA, and the temporary fixing substrate 42 is removed, whereby the semiconductor structure 102, which has a structure in which the substrate-to-substrate bonding layer 32A and the substrate-to-substrate bonding layer 32B are added between the two composite substrates in the semiconductor structure 100, is obtained (see FIG. 8B).

### Third Embodiment

The production method according to the third embodiment is a method of producing a semiconductor structure that includes the steps of:
preparing a semiconductor substrate including a semiconductor substrate main body, a semiconductor substrate bonding layer that is arranged on the semiconductor substrate main body and includes an insulating layer and an electrode, and a through electrode;
preparing at least two composite substrates that are each temporarily fixed on a temporary fixing substrate and include two-dimensionally arranged plural silicon dies and an organic gap fill material filled between the plural silicon dies;
pasting a first composite substrate onto the semiconductor substrate bonding layer of the semiconductor substrate, hybrid-bonding the semiconductor substrate and the plural silicon dies of the first composite substrate, and then peeling off the temporary fixing substrate from the first composite substrate to expose the plural silicon dies; and
where n is defined as an integer of 1 or larger, performing operations of pasting and hybrid-bonding an (n+1)^{th} composite substrate onto an n^{th} composite substrate on the semiconductor substrate bonding layer of the semiconductor substrate either directly or via another layer (e.g., a substrate-to-substrate bonding layer that includes an insulating layer and an electrode), and then peeling off the temporary fixing substrate from the (n+1)^{th} composite substrate and thereby exposing the plural silicon dies, the operations being sequentially performed for integers from 1 to n to obtain a semiconductor structure.

If necessary, the production method according to the third embodiment may also include other steps.

The production method according to the third embodiment preferably satisfies at least one of the following:
in the step of preparing at least two composite substrates, at least one of the at least two composite substrates includes a through electrode; or
after the step of preparing at least two composite substrates, a through electrode is formed in at least one of the at least two composite substrates.

In other words, in a preferred embodiment, a through electrode may be formed in advance in the composite substrates to be prepared, or may be formed during the process of producing a semiconductor structure.

At least one of the temperature of hybrid-bonding the semiconductor substrate and the plural silicon dies of the first composite substrate, or the temperature of pasting and hybrid-bonding the (n+1)^{th} composite substrate onto the n^{th} composite substrate either directly or via another layer is preferably from 150° C. to 250° C.

By the production method according to the third embodiment, for example, the semiconductor structure 400 that is the fourth specific example described above can be produced.

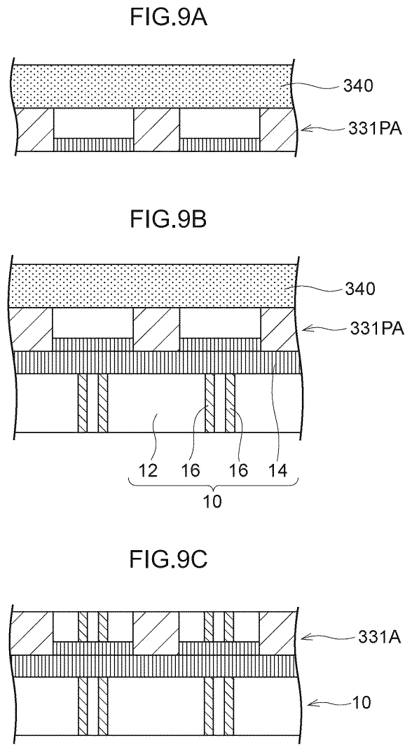

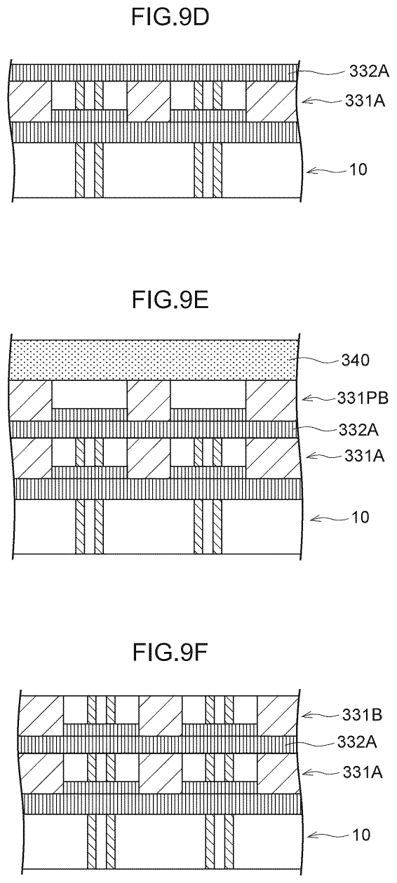

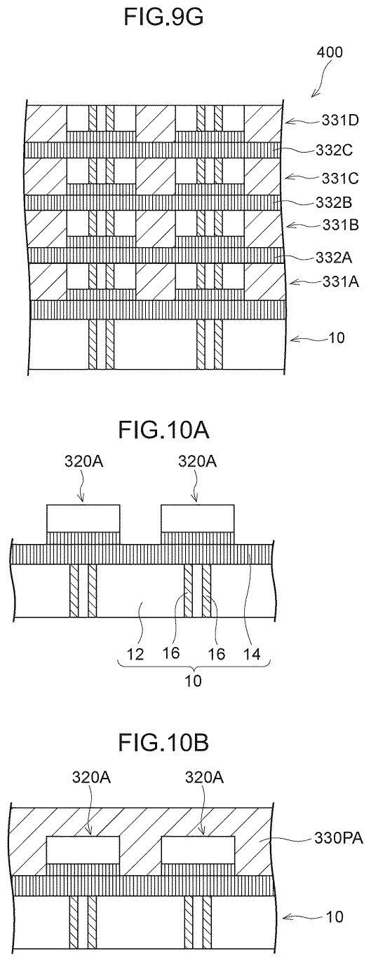

FIGS. 9A to 9G are schematic process diagrams illustrating one example of the production method according to the third embodiment for producing the semiconductor structure 400 that is the fourth specific example described above.

FIGS. 9A and 9B illustrate the step of preparing a semiconductor substrate, the step of preparing at least two composite substrates, and the step of forming through electrodes in plural silicon dies of a first composite substrate.

In the step of preparing a semiconductor substrate, a semiconductor substrate 10 (see FIG. 9B) including: a semiconductor substrate main body 12; a semiconductor substrate bonding layer 14 which is arranged on the semiconductor substrate main body 12 and includes an insulating layer and an electrode; and through electrodes 16 is prepared.

In the step of preparing at least two composite substrates, at least two composite substrates (e.g., composite substrates 331PA) temporarily fixed on a temporary fixing substrate 340 are prepared.

It is sufficient as long as the at least two composite substrates are each a composite substrate that includes two-dimensionally arranged plural silicon dies and an organic gap fill material filled between the plural silicon dies. In the at least two composite substrates, the size and number of the silicon dies may each be the same or different.

The composite substrate 331PA which is the first composite substrate is pasted onto the semiconductor substrate bonding layer 14 of the semiconductor substrate 10, and the semiconductor substrate 10 and the plural silicon dies of the first composite substrate 331PA are hybrid-bonded, after which the temporary fixing substrate 340 is peeled off from the composite substrate 331PA to expose the plural silicon dies, and through electrodes are subsequently formed in the thus exposed plural silicon dies. By the formation of the through electrodes in the silicon dies of the composite substrate 331PA, a composite substrate 331A is obtained (see FIG. 9C).

FIGS. 9D to 9G illustrate the steps of obtaining a semiconductor structure.

First, as illustrated in FIG. 9D, a substrate-to-substrate bonding layer 332A which includes an insulating layer and an electrode is formed on the composite substrate 331A.

Next, as illustrated in FIG. 9E, a second composite substrate 331PB (with the temporary fixing substrate 340) is pasted and hybrid-bonded onto the thus formed substrate-to-substrate bonding layer 332A.

Subsequently, the temporary fixing substrate 340 is peeled off from the second composite substrate 331PB to expose the plural silicon dies, after which through electrodes are formed in the thus exposed plural silicon dies of the composite substrate 331PB, whereby a composite substrate 331B is obtained (see FIG. 9F).

A series of the above-described operations illustrated in FIGS. 9D and 9F are performed n times (wherein, n is an integer of 1 or larger).

In other words, where n is defined as an integer of 1 or larger, the operations of pasting and hybrid-bonding the (n+1)^{th} composite substrate onto the n^{th} composite substrate on the semiconductor substrate bonding layer of the semiconductor substrate either directly or via another layer (e.g., a substrate-to-substrate bonding layer that includes an insulating layer and an electrode), and then peeling off the temporary fixing substrate from the (n+1)^{th} composite substrate and thereby exposing the plural silicon dies are sequentially performed for integers from 1 to n.

In this example, n is 3.

In the semiconductor structure according to this example, four composite substrates, including the first composite substrate, are stacked in layers on the semiconductor substrate 10.

In the above-described manner, the semiconductor structure 400 illustrated in FIG. 9G (note: substantially the same as the semiconductor structure 400 illustrated in FIG. 4) is obtained.

In the third embodiment, n is preferably from 1 to 30, more preferably from 1 to 20.

### Fourth Embodiment

The production method according to the fourth embodiment is a method of producing a semiconductor structure that includes the steps of:
preparing a semiconductor substrate including a semiconductor substrate main body, a semiconductor substrate bonding layer that is arranged on the semiconductor substrate main body and includes an insulating layer and an electrode, and a through electrode;
two-dimensionally arranging and hybrid-bonding plural silicon dies on the semiconductor substrate bonding layer of the semiconductor substrate, and then filling gaps between the plural silicon dies with an organic gap fill material to form a first composite substrate; and
where n is defined as an integer of 1 or larger, performing operations of two-dimensionally arranging and hybrid-bonding plural silicon dies onto an n^{th} composite substrate on the semiconductor substrate bonding layer of the semiconductor substrate either directly or via another layer (e.g., a substrate-to-substrate bonding layer that includes an insulating layer and an electrode), and then filling gaps between the plural silicon dies with an organic gap fill material to form an (n+1)^{th} composite substrate, the operations being sequentially performed for integers from 1 to n to obtain a semiconductor structure.

If necessary, the production method according to the fourth embodiment may also include other steps.

The production method according to the fourth embodiment preferably satisfies at least one of the following:
the plural silicon dies for the formation of at least one of the first to the (n+1)^{th} composite substrates include a through electrode; or
a through electrode is formed in at least one of the first to the (n+1)^{th} composite substrates.

In other words, in a preferred embodiment, a through electrode may be formed in advance in the composite substrates to be prepared, or may be formed during the process of producing a semiconductor structure.

In the same manner as the production method according to the third embodiment, by the production method according to the fourth embodiment, for example, the semiconductor structure 400 that is the fourth specific example described above can be produced.

In other words, the semiconductor structure 400 that is the fourth specific example described above can be produced by:
the above-described production method according to the third embodiment in which composite substrates are pasted to a semiconductor substrate; or
the below-described production method according to the fourth embodiment in which composite substrates are formed one by one in layers on a semiconductor substrate, rather than being pasted to the semiconductor substrate.

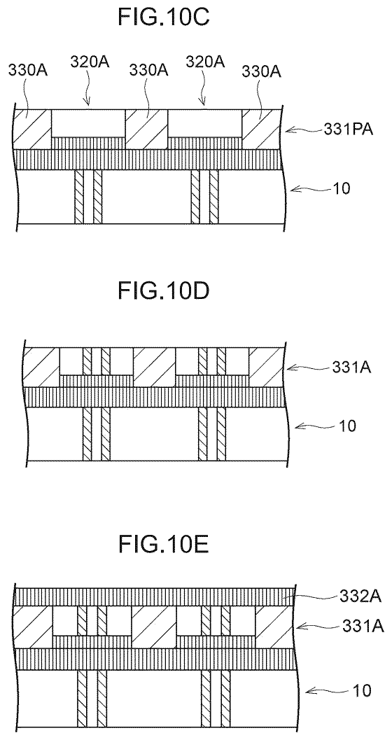

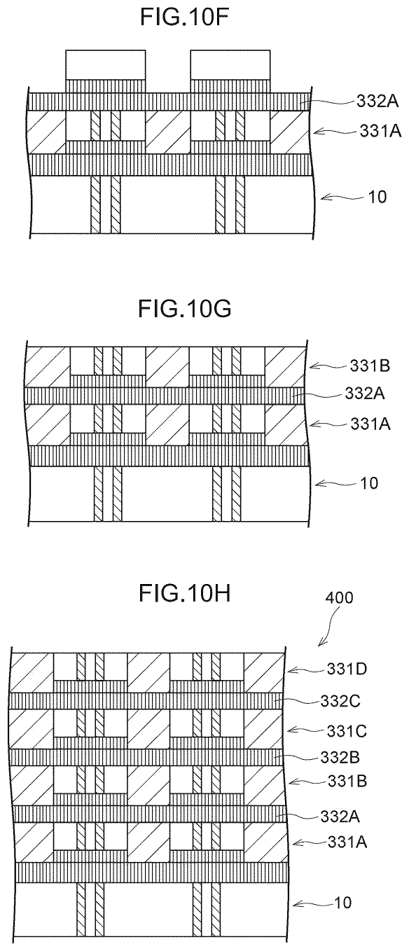

FIGS. 10A to 10G are schematic process diagrams illustrating one example of the production method according to the fourth embodiment for producing the semiconductor structure 400 that is the fourth specific example described above.

FIGS. 10A to 10D illustrate the step of preparing a semiconductor substrate, and the step of forming a first composite substrate and forming through electrodes in plural silicon dies of the first composite substrate.

In the step of preparing a semiconductor substrate, a semiconductor substrate 10 (see FIG. 10A) including: a semiconductor substrate main body 12; a semiconductor substrate bonding layer 14 which is arranged on the semiconductor substrate main body 12 and includes an insulating layer and an electrode; and through electrodes 16 is prepared.

Next, as illustrated in FIG. 10A, plural silicon dies 320A are two-dimensionally arranged and hybrid-bonded on the semiconductor substrate bonding layer 14 of the semiconductor substrate 10.

Then, as illustrated in FIG. 10B, on the semiconductor substrate 10 on which the plural silicon dies 20B have been hybrid-bonded, an organic gap fill material layer 330PA is formed such that it fills gaps between the plural silicon dies 320A and covers the plural silicon dies 320A.

Subsequently, as illustrated in FIG. 10C, the organic gap fill material layer 330PA is polished to expose the surfaces of the plural silicon dies 320A, leaving an organic gap fill material 330A between the plural silicon dies 320A. As a result, a composite substrate 331PA, which includes the plural silicon dies 320A that are two-dimensionally arranged on the semiconductor substrate bonding layer 14 of the semiconductor substrate 10, and the organic gap fill material 330A filled between the plural silicon dies 320A, is obtained (FIG. 10C).

Thereafter, as illustrated in FIGS. 10C and 10D, through electrodes are formed in the plural silicon dies of the composite substrate 331PA, whereby a composite substrate 331A is obtained on the semiconductor substrate bonding layer 14 of the semiconductor substrate 10. In other words, the composite substrate 331A is the composite substrate 331PA in which through electrodes are formed in the plural silicon dies.

FIGS. 10E to 10H illustrate the steps of obtaining a semiconductor structure.

First, as illustrated in FIG. 10E, a substrate-to-substrate bonding layer 332A which includes an insulating layer and an electrode is formed on the composite substrate 331A.

Next, as illustrated in FIGS. 10F and 10G, on the thus formed substrate-to-substrate bonding layer 332A, a composite substrate 331B which is a second composite substrate is formed in the same manner as the composite substrate 331A (i.e., first composite substrate).

A series of the above-described operations illustrated in FIGS. 10F and 10G are performed n times (wherein, n is an integer of 1 or larger).

In other words, where n is defined as an integer of 1 or larger, the operations of two-dimensionally arranging and hybrid-bonding plural silicon dies onto an n^{th} composite substrate on the semiconductor substrate bonding layer of the semiconductor substrate either directly or via another layer (e.g., a substrate-to-substrate bonding layer that includes an insulating layer and an electrode), and then filling gaps between the plural silicon dies with an organic gap fill material to form an (n+1)^{th} composite substrate are sequentially performed for integers from 1 to n.

In this example, n is 3.

In the semiconductor structure according to this example, four composite substrates, including the first composite substrate, are stacked in layers on the semiconductor substrate 10.

In the above-described manner, the semiconductor structure 400 illustrated in FIG. 10H (note: substantially the same as the semiconductor structure 400 illustrated in FIG. 4) is obtained.

In the fourth embodiment, n is preferably from 1 to 30, more preferably from 1 to 20.

### [Elements in Semiconductor Structure of Disclosure and Production Method Thereof]

Elements in the semiconductor structure of the disclosure and the production method thereof will now be described.

### <Composite Substrate>

The semiconductor structure of the disclosure includes composite substrates.

The composite substrates each include two-dimensionally arranged plural silicon dies, and an organic gap fill material filled between the plural silicon dies.

The semiconductor structure A (i.e., the semiconductor structure of the disclosure that includes plural composite substrates) includes plural composite substrates that are stacked directly or via another layers.

The plural composite substrates each include two-dimensionally arranged plural silicon dies, and an organic gap fill material filled between the plural silicon dies.

### (Silicon Dies)

Each composite substrate in the semiconductor structure of the disclosure includes two-dimensionally arranged plural silicon dies.

Further, the semiconductor structure of the disclosure includes a silicon die that is hybrid-bonded, either directly or via another layer, to at least one of the plural silicon dies of the composite substrate.

As the silicon dies of the disclosure, ordinary silicon dies obtained by forming an integrated circuit on a silicon substrate (e.g., a silicon wafer) and cutting this silicon substrate into chips can be used.

The spacing of the plural silicon dies (i.e., the distance between the side surface of one silicon die and the side surface of an adjacent silicon die) is preferably from 0.1 μm to 100,000 μm, more preferably from 1 μm to 10,000 μm, still more preferably from 50 μm to 1,000 μm.

The silicon dies have a thickness of preferably from 5 μm to 700 μm, more preferably from 10 μm to 300 μm, still more preferably from 15 μm to 100 μm.

The silicon dies preferably each include a silicon die main body, and a silicon die bonding layer arranged on at least one surface of the silicon die main body.

The silicon die bonding layer is preferably arranged on at least the surface of the silicon die main body that is to be hybrid-bonded.

The silicon die main body is, for example, a silicon substrate (e.g., a silicon wafer) having an integrated circuit formed thereon, which is cut out in the form of a chip.

The silicon die bonding layer may include an insulating layer, and an electrode (e.g., a Cu electrode) penetrating through the insulating layer.

In the disclosure, an “electrode penetrating through an insulating layer” refers to an electrode that is arranged in an insulating layer and exposed from both sides of the insulating layer. The electrode may penetrate through the insulating layer in a linear manner, or in a curved (e.g., meandering) manner. The electrode may be a single member (e.g., a metal member), or a composite member composed of plural members (e.g., metal members).

Examples of the material of the electrode in the silicon die bonding layer include Cu, Sn, Au, Ag, Al, and solder.

The electrode in the silicon die bonding layer preferably contains Cu.

The electrode in the silicon die bonding layer can be formed by, for example, any known production method such as a damascene process or a semi-additive process.

The insulating layer in the silicon die bonding layer preferably includes at least one selected from the group consisting of a SiO₂ layer, a SiCN layer, a SiN layer, and a siloxane bond-containing resin layer.

The SiO₂ layer, the SiCN layer, and the SiN layer that are included as the insulating layer can each be formed by a vapor deposition method, such as sputtering, chemical vapor deposition (CVD), or atomic layer deposition (ALD).

Examples of a siloxane bond-containing resin in the siloxane bond-containing resin layer included as the insulating layer include polybenzoxazoles, divinylsiloxane benzocyclobutene polymers, siloxane imide polymers, and epoxy-modified siloxane polymers.

The siloxane bond-containing resin may contain a structure represented by any of the following Formulae (1) to (3).

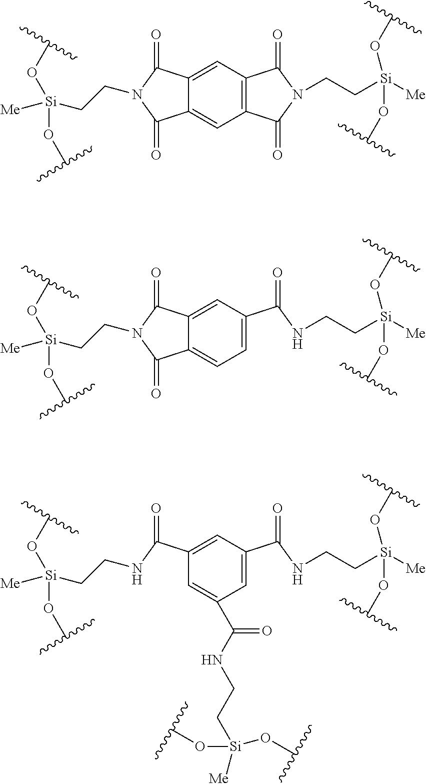 [SMILES: *O[Si](C)(CCn1c(=O)c2cc3c(=O)n(CC[Si](C)(O*)O*)c(=O)c3cc2c1=O)O* ; *O[Si](C)(CCNC(=O)c1ccc2c(c1)C(=O)N(CC[Si](C)(O*)O*)C2=O)O* ; *O[Si](C)(CCNC(=O)c1cc(C(=O)NCC[Si](C)(O*)O*)cc(C(=O)NCC[Si](C)(O*)O*)c1)O*]

In these structures having a Si—O bond (siloxane bond), the group bound to Si is optionally substituted with an alkylene group, a phenylene group, or the like. For example, the group may have a structure of (—O—)ₓ(R₁)_{y}Si—(R₂)—Si(R₁)_{y}(—O—)ₓ or the like (wherein, R₁ represents a methyl group or the like; R₂ represents an alkylene group, a phenylene group, or the like; each of x and y independently represents an integer of 0 or larger; and x+y is 3).

Examples of a material for the formation of a Si—O bond include compounds represented by the following Formulae (4) and (5).

The structures represented by Formulae (1) and (2) can be produced by, for example, heating and reacting the compounds represented by Formulae (4) and (5).

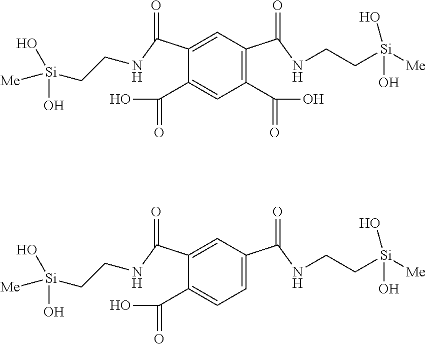 [SMILES: C[Si](O)(O)CCNC(=O)c1cc(C(=O)NCC[Si](C)(O)O)c(C(=O)O)cc1C(=O)O ; C[Si](O)(O)CCNC(=O)c1ccc(C(=O)O)c(C(=O)NCC[Si](C)(O)O)c1]

The siloxane bond-containing resin layer as the insulating layer in the silicon die bonding layer can be formed by, for example, spin coating, slit coating, spray coating, screen printing, squeegeeing, or inkjet printing.

As a composition used for the formation of the siloxane bond-containing resin layer, any one example of the below-described organic gap fill material forming solution can be applied.

### <Organic Gap Fill Material>

In the disclosure, each composite substrate includes an organic gap fill material filled between the plural silicon dies.

The organic gap fill material may be provided at a place other than the composite substrate (e.g., around a silicon die that is hybrid-bonded, either directly or via another layer, to at least one of the plural silicon dies of the composite substrate).

In the disclosure, the organic gap fill material may be any gap fill material that contains an organic material, and may be a gap fill material that contains an organic material but not an inorganic material, or a gap fill material that contains both an organic material and an inorganic material.

As described above, in the semiconductor structure of the disclosure, an organic gap fill material is applied as the gap fill material filled between the plural silicon dies, whereby warping of the semiconductor structure is inhibited as compared to a case where an inorganic gap fill material is applied as the gap fill material filled between the plural silicon dies.

The organic material contained in the organic gap fill material has a glass transition temperature of preferably from 110° C. to 300° C., more preferably from 120° C. to 300° C., still more preferably from 150° C. to 300° C.

The glass transition temperature can be measured by the following method.

In other words, a test piece of the organic material is prepared at a size of 4 mm in width and 20 mm in length. The glass transition temperature of this test piece is measured by TMA using a thermomechanical analyzer (TMA-50) manufactured by Shimadzu Corporation under the following measurement conditions: temperature range=25° C. to 350° C.; heating rate=5° C./min; and load=14 g/mm², in the tensile mode. The glass transition temperature (Tg) can be determined from the inflection point of the thus obtained temperature-test piece elongation curve.

The organic material contained in the organic gap fill material is preferably a resin. Examples of the resin include polyimides, polyamides, polyamideimides, maleimide resins, parylene, polyarylene ethers, polybenzoxazoles, benzocyclobutene resins, epoxy resins, and siloxane bond-containing resins.

The organic gap fill material may contain only a single kind of organic material (preferably a resin), or may contain two or more kinds of organic materials in combination.

The content of the organic material (preferably a resin) in the organic gap fill material is preferably 30% by mass or more, more preferably 50% by mass or more, still more preferably 60% by mass or more, yet still more preferably 80% by mass or more, with respect to a total amount of the organic gap fill material.

The organic gap fill material may also contain an inorganic material.

The inorganic material may be, for example, an inorganic filler.

Examples of the inorganic filler include silica, alumina, magnesia, titania, antimony oxide, talc, clay, montmorillonite, hydrotalcite, synthetic mica, calcium carbonate, aluminum hydroxide, and magnesium hydroxide.

The organic gap fill material may contain only a single kind of inorganic filler, or may contain two or more kinds of inorganic fillers in combination.

The content of the inorganic filler is, for example, 70% by mass or less, preferably 50% by mass or less, still more preferably 40% by mass or less, yet still more preferably 20% by mass or less, with respect to a total amount of the organic gap fill material.

The organic gap fill material can be formed by, for example, forming a film by a wet process and removing unnecessary parts of the thus formed film.

The removal of the unnecessary parts can be performed by, for example, polishing.

The polishing can be performed in accordance with a conventional method, such as mechanical polishing, chemical polishing, or chemical mechanical polishing.

When a film is formed by a wet process, for example, an organic gap fill material forming solution containing a resin precursor is applied and heated to obtain the film.

The purpose of the heating is to dry a solvent in the applied solution and to cure the resin precursor in the applied solution to obtain a resin. Heating for drying and heating for curing the resin precursor may be performed separately.

The application can be performed by any known method, such as spin coating, slit coating, spray coating, screen printing, squeegeeing, or inkjet printing.

One example of the organic gap fill material forming solution is described below.

### <Hybrid Bonding>

In the semiconductor structure of the disclosure, another silicon die is hybrid-bonded to at least one of the plural silicon dies of the composite substrates, either directly or via another layer.

In the semiconductor structure A, plural silicon dies of two of the plural composite substrates that are adjacent to each other in the stacking direction are hybrid-bonded either directly or via another layer.

The meaning of hybrid-bonding and the preferred temperature range of hybrid-bonding are as described above.

### <Through Electrode>

The semiconductor structure of the disclosure may include through electrodes that penetrate through the silicon dies or the organic gap fill material.

The through electrode is not particularly limited, and any known through electrode can be applied.

For example, in the semiconductor structure A, among the plural composite substrates, at least one of the composite substrates arranged as outermost layers (i.e., the plural silicon dies or the organic gap fill material) may include a through electrode. This through electrode enables to establish an electrical connection between a portion of the semiconductor structure other than the outermost layers and a circuit board outside the semiconductor structure.

Further, when the semiconductor structure of the disclosure includes three or more composite substrates, it is preferred that, among the three or more composite substrates, a composite substrate X that is a composite substrate other than two composite substrates constituting outermost layers also includes a through electrode.

By this, the plural silicon dies of the composite substrate adjacent to one of the surfaces of the composite substrate X and the plural silicon dies of the composite substrate adjacent to the another surface of the composite substrate X can be electrically connected via the through electrode in the composite substrate X.

The composite substrate X may be arranged in a single layer, or in two or more layers, between the two composite substrates constituting the outermost layers.

### <Substrate-to-Substrate Bonding Layer>

In the semiconductor structure of the disclosure, two silicon dies adjacent to each other in the stacking direction may be hybrid-bonded via a substrate-to-substrate bonding layer provided as other layer.

In the semiconductor structure A, plural silicon dies of two of the plural composite substrates that are adjacent to each other in the stacking direction may be hybrid-bonded via the substrate-to-substrate bonding layer provided as other layer.

In the disclosure, the substrate-to-substrate bonding layer is a layer that includes an insulating layer and an electrode.

Preferred aspects of the substrate-to-substrate bonding layer are the same as those of the silicon die bonding layer.

### <Semiconductor Substrate>

The semiconductor structure of the disclosure may further include a semiconductor substrate.

The semiconductor substrate includes: a semiconductor substrate main body; a semiconductor substrate bonding layer that is arranged on the semiconductor substrate main body and includes an insulating layer and an electrode; and a through electrode that penetrates through the semiconductor substrate main body.

In this case, it is preferred that a semiconductor substrate bonding layer side of the semiconductor substrate is hybrid-bonded with the plural silicon dies of a composite substrate arranged as one of outermost layers among the plural composite substrates.

### (Semiconductor Substrate Main Body)

The semiconductor substrate may include a semiconductor substrate main body.

The material of the semiconductor substrate main body is not particularly limited, and may be any material that is commonly used as a semiconductor substrate.

The substrate main body preferably contains at least one element selected from the group consisting of Si, Al, Ti, Zr, Hf, Fe, Ni, Cu, Ag, Au, Ga, Ge, Sn, Pd, As, Pt, Mg, In, Ta, and Nb.

More specific examples of the material of the semiconductor substrate main body include:
semiconductors (e.g., Si, InP, GaN, GaAs, InGaAs, InGaAlAs, and SiC);
oxides, carbides, and nitrides (e.g., borosilicate glass (PYREX (registered trademark)), quartz glass (SiO₂), sapphire, ZrO₂, Si₃N₄, and AlN);
piezoelectrics and dielectrics (e.g., BaTiO₃, LiNbO₃, SrTiO₃, and diamond);
metals (e.g., Al, Ti, Fe, Cu, Ag, Au, Pt, Pd, Ta, and Nb); and
resins (e.g., polydimethylsiloxanes (PDMS), epoxy resins, phenolic resins, polyimides, benzocyclobutene resins, and polybenzoxazoles.

The semiconductor substrate main body may contain any of these materials singly, or may contain two or more of these materials in combination.

The semiconductor substrate main body is preferably a silicon substrate, a GaAs substrate, a SiC substrate, a diamond substrate, a glass substrate, or a resin substrate, typically a silicon substrate.

The semiconductor substrate main body may have a multi-layer structure.

### (Semiconductor Substrate Bonding Layer)

The semiconductor substrate may include a semiconductor substrate bonding layer arranged on the semiconductor substrate main body.

The semiconductor substrate bonding layer includes an insulating layer and an electrode.

Preferred aspects of the semiconductor substrate bonding layer are the same as those of the silicon die bonding layer.

### (Through Electrode)

The semiconductor substrate may include a through electrode penetrating through the semiconductor substrate main body. This through electrode enables to establish an electrical connection between the semiconductor structure and a circuit board outside the semiconductor structure.

The through electrode is not particularly limited, and any known through electrode can be applied.

### <Temporary Fixing Substrate>

In the production methods according to the first to the third embodiments, a temporary fixing substrate is used.

As the temporary fixing substrate, for example, a silicon substrate, a glass substrate, or a resin substrate can be used.

A silicon die or a composite substrate can be temporarily fixed on the temporary fixing substrate by, for example:
a method using an adhesive, such as an acryl or an epoxy polymer;
a method using a heat-resistant resin, such as a polyimide, a polyamideimide, a polymaleimide, or a siloxane polymer; or
a direct bonding of SiO₂ molecules.

In the production methods according to the first to the third embodiments, the temporary fixing substrate can be removed from a laminated body by, for example, any of the following methods.

When the temporary fixing substrate is temporarily fixed using an acrylic adhesive or an epoxy adhesive, the temporary fixing substrate can be removed by, for example, thermal foaming, mechanical peeling, thermal sliding, or laser peeling.

When the temporary fixing substrate is temporarily fixed using a heat-resistant resin such as a polyimide, a polyamideimide, a polymaleimide, or a siloxane polymer, the temporary fixing substrate can be removed by, for example, laser peeling, mechanical peeling, or thermal sliding.

When the temporary fixing substrate is temporarily fixed by direct bonding of SiO₂ molecules, the temporary fixing substrate can be removed by, for example, laser peeling with infrared rays or the like.

### <One Example of Organic Gap Fill Material Forming Solution>

The above-described organic gap fill material can be formed using, for example, an organic gap fill material forming solution.

The organic gap fill material forming solution may be, for example, a solution containing a resin material.

The below-described solution containing a resin solution can also be used as a solution for forming a siloxane bond-containing resin layer as the insulating layer in the silicon die bonding layer or the insulating layer in the semiconductor substrate bonding layer.

The solution containing a resin material preferably contains:
a compound (A) that has a cationic functional group containing at least one of a primary nitrogen atom or a secondary nitrogen atom, and has a weight-average molecular weight of from 90 to 400,000;
a crosslinking agent (B) having three or more —C(═O)OX groups (wherein, X represents a hydrogen atom or an alkyl group having from 1 to 6 carbon atoms) in the molecule, in which from one to six of the three or more —C(═O)OX groups are —C(═O)OH groups, and which has a weight-average molecular weight of from 200 to 600; and
a polar solvent (D).

### —Compound (A)—

The compound (A) is a compound that has a cationic functional group containing at least one of a primary nitrogen atom or a secondary nitrogen atom, and has a weight-average molecular weight of from 90 to 400,000. The cationic functional group is not particularly limited as long as it is a functional group that can bear a positive charge and contains at least one of a primary nitrogen atom or a secondary nitrogen atom.

The compound (A) may also contain a tertiary nitrogen atom in addition to the primary nitrogen atom and the secondary nitrogen atom.

In the disclosure, a “primary nitrogen atom” refers to a nitrogen atom bound to only two hydrogen atoms and one atom other than a hydrogen atom (e.g., a nitrogen atom contained in a primary amino group (—NH₂ group)), or a nitrogen atom (cation) bound to only three hydrogen atoms and one atom other than a hydrogen atom.

A “secondary nitrogen atom” refers to a nitrogen atom bound to only one hydrogen atom and two atoms other than a hydrogen atom (i.e., a nitrogen atom contained in a functional group represented by the following Formula (a)), or a nitrogen atom (cation) bound to only two hydrogen atoms and two atoms other than a hydrogen atom.

Further, a “tertiary nitrogen atom” refers to a nitrogen atom bound to only three atoms other than a hydrogen atom (i.e., a nitrogen atom that is a functional group represented by the following Formula (b)), or a nitrogen atom (cation) bound to only one hydrogen atom and three atoms other than a hydrogen atom.

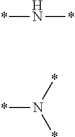

In Formulae (a) and (b), * represents a position of binding with an atom other than a hydrogen atom.

The functional group represented by Formula (a) may be a functional group constituting a part of a secondary amino group (—NHR^{a} group, wherein R^{a} represents an alkyl group), or may be a divalent linking group contained in a polymer skeleton.

The functional group represented by Formula (b) (i.e., a tertiary nitrogen atom) may be a functional group constituting a part of a tertiary amino group (—NR^{b}R^{c} group, wherein each of R^{b} and R^{c} independently represents an alkyl group), or may be a trivalent linking group contained in a polymer skeleton.

The compound (A) has a weight-average molecular weight of from 90 to 400,000. Examples of the compound (A) include aliphatic amines, compounds having a siloxane bond (Si—O bond) and an amino group, and amine compounds having a ring structure without a Si—O bond in the molecule. When the compound (A) is an aliphatic amine, the weight-average molecular weight thereof is preferably from 10,000 to 200,000. When the compound (A) is a compound having a siloxane bond (Si—O bond) and an amino group, the weight-average molecular weight thereof is preferably from 130 to 10,000, more preferably from 130 to 5,000, still more preferably from 130 to 2,000. When the compound (A) is an amine compound having a ring structure without a Si—O bond in the molecule, the weight-average molecular weight thereof is preferably from 90 to 600.

In the disclosure, the weight-average molecular weight refers to a weight-average molecular weight in terms of polyethylene glycol, which is measured by gel permeation chromatography (GPC) for a compound other than a monomer.

Specifically, the weight-average molecular weight is determined by detecting the refractive index at a flow rate of 1.0 mL/min using an aqueous solution of sodium nitrate having a concentration of 0.1 mol/L as a developing solvent and an analyzer SHODEX DET RI-101 along with two kinds of analytical columns (TSKgel G6000PWXL-CP and TSKgel G3000PWXL-CP, manufactured by Tosoh Corporation), and performing calculation using an analysis software (EMPOWER3, manufactured by Waters Corporation) and polyethylene glycol/polyethylene oxide as a standard.

If necessary, the compound (A) may further have an anionic functional group, a nonionic functional group, or the like.

The nonionic functional group may be a hydrogen bond acceptor or a hydrogen bond donor. Examples of the nonionic functional group include a hydroxy group, a carbonyl group, and an ether group (—O—).

The anionic functional group is not particularly limited as long as it is a functional group that can bear a negative charge. Examples of the anionic functional group include a carboxylic acid group, a sulfonic acid group, and a sulfuric acid group.

Examples of the compound (A) include aliphatic amines, more specifically: polyalkyleneimines that are polymers of alkyleneimines, such as ethyleneimine, propyleneimine, butyleneimine, pentyleneimine, hexyleneimine, heptyleneimine, octyleneimine, trimethyleneimine, tetramethyleneimine, pentamethyleneimine, hexamethyleneimine, and octamethyleneimine; polyallylamines; and polyacrylamides.

A polyethyleneimine (PEI) can be produced by any known method described in, for example, Japanese Patent Publication (JP-B) No. S43-8828, JP-B No. S49-33120, Japanese Patent Application Laid-Open (JP-A) No. 2001-213958, or WO 2010/137711. A polyalkyleneimine other than a polyethyleneimine can also be produced by the same method as a polyethyleneimine.

The compound (A) is also preferably a derivative of any of the aforementioned polyalkyleneimines (a polyalkyleneimine derivative; particularly preferably a polyethyleneimine derivative). The polyalkyleneimine derivative is not particularly limited as long as it is a compound that can be produced using any of the aforementioned polyalkyleneimines. Specific examples of the polyalkyleneimine derivative include: polyalkyleneimine derivatives obtained by introducing an alkyl group (preferably an alkyl group having from 1 to 10 carbon atoms), an aryl group, or the like into a polyalkyleneimine; and polyalkyleneimine derivatives obtained by introducing a crosslinkable group such as a hydroxy group into a polyalkyleneimine.

These polyalkyleneimine derivatives can be produced by a method that is usually performed using any of the aforementioned polyalkyleneimines. Specifically, the polyalkyleneimine derivatives can be produced, for example, in accordance with the method described in JP-A No. H06-016809 or the like.

As the polyalkyleneimine derivative, a highly branched polyalkyleneimine obtained by allowing a cationic functional group-containing monomer to react with a polyalkyleneimine and thereby improving the branching degree of the polyalkyleneimine is also preferred.

Examples of a method of obtaining a highly branched polyalkyleneimine include: a method of allowing a cationic functional group-containing monomer to react with a polyalkyleneimine having plural secondary nitrogen atoms in its skeleton, and thereby substituting at least one of the plural secondary nitrogen atoms with the cationic functional group-containing monomer; and a method of allowing a cationic functional group-containing monomer to react with a polyalkyleneimine having plural primary nitrogen atoms at its terminals, and thereby substituting at least one of the plural primary nitrogen atoms with the cationic functional group-containing monomer.

Examples of the cationic functional group introduced to improve the branching degree include an aminoethyl group, an aminopropyl group, a diaminopropyl group, an aminobutyl group, a diaminobutyl group, and a triaminobutyl group; however, from the standpoint of reducing the equivalent of the cationic functional group and increasing the density of the cationic functional group, an aminoethyl group is preferred.

The above-described polyethyleneimine and derivatives thereof may be commercially available products. The polyethyleneimine and derivatives thereof may be selected as appropriate from those that are commercially available from, for example, Nippon Shokubai Co., Ltd., BASF SE, and MP Biomedicals, LLC.

Examples of the compound (A) include compounds having a Si—O bond and an amino group, in addition to the above-described aliphatic amines.

A compound having a Si—O bond and an amino group as the compound (A) is suitable as a material of a siloxane bond-containing resin.

Examples of the compound having a Si—O bond and an amino group include siloxanediamines, amino group-containing silane coupling agents, and siloxane polymers of amino group-containing silane coupling agents.

Examples of the amino group-containing silane coupling agents include compounds represented by the following Formula (A-3).

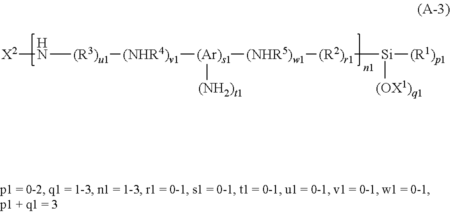

In Formula (A-3), R¹ represents an optionally substituted alkyl group having from 1 to 4 carbon atoms; each of R² and R³ independently represents an optionally substituted alkylene group having from 1 to 12 carbon atoms (optionally containing a carbonyl group, an ether group, or the like in the skeleton), an ether group, or a carbonyl group; each of R⁴ and R⁵ independently represents an optionally substituted alkylene group having from 1 to 4 carbon atoms, or a single bond; Ar represents a divalent or trivalent aromatic ring; X¹ represents hydrogen or an optionally substituted alkyl group having from 1 to 5 carbon atoms; X² represents hydrogen, a cycloalkyl group, a heterocyclic group, an aryl group, or an optionally substituted alkyl group having from 1 to 5 carbon atoms (optionally containing a carbonyl group, an ether group, or the like in the skeleton); and plural R¹s, R²s, R³s, R⁴s, R⁵s, and X¹s may each be the same or different.

Each of the substituents of the alkyl groups and the alkylene groups that are represented by R¹, R², R³, R⁴, R⁵, X¹, and X² may independently be, for example, an amino group, a hydroxy group, an alkoxy group, a cyano group, a carboxylic acid group, a sulfonic acid group, or a halogen.

Examples of the divalent or trivalent aromatic ring represented by Ar include a divalent or trivalent benzene ring. Examples of the aryl group represented by X² include a phenyl group, a methylbenzyl group, and a vinylbenzyl group.

Specific examples of the silane coupling agent represented by Formula (A-3) include N-(2-aminoethyl)-3-aminopropylmethyldiethoxysilane, N-(2-aminoethyl)-3-aminopropyltriethoxysilane, N-(2-aminoethyl)-3-aminoisobutyldimethylmethoxysilane, N-(2-aminoethyl)-3-aminoisobutylmethyldimethoxysilane, N-(2-aminoethyl)-11-aminoundecyltrimethoxysilane, 3-aminopropyltrimethoxysilane, 3-aminopropyltriethoxysilane, N-phenyl-3-aminopropyltrimethoxysilane, (aminoethylaminoethyl)phenyltriethoxysilane, methylbenzylaminoethylaminopropyltrimethoxysilane, benzylaminoethylaminopropyltriethoxysilane, 3-ureidopropyltriethoxysilane, (aminoethylaminoethyl) phenethyltrimethoxysilane, (aminoethylaminomethyl) phenethyltrimethoxysilane, N-[2-[3-(trimethoxysilyl) propylamino]ethyl]ethylenediamine, 3-aminopropyldiethoxymethylsilane, 3-aminopropyldimethoxymethylsilane, 3-aminopropyldimethylethoxysilane, 3-aminopropyldimethylmethoxysilane, trimethoxy[2-(2-aminoethyl)-3-aminopropyl]silane, diaminomethylmethyldiethoxysilane, methylaminomethylmethyldiethoxysilane, p-aminophenyltrimethoxysilane, N-methylaminopropyltriethoxysilane, N-methylaminopropylmethyldiethoxysilane, (phenylaminomethyl)methyldiethoxysilane, acetamidopropyltrimethoxysilane, and hydrolysates thereof.

Examples of an amino group-containing silane coupling agent other than that of Formula (A-3) include N,N-bis[3-(trimethoxysilyl) propyl]ethylenediamine, N,N-bis[3-(trimethoxysilyl) propyl]ethylenediamine, bis[(3-triethoxysilyl) propyl]amine, piperazinylpropylmethyldimethoxysilane, bis[3-(triethoxysilyl) propyl]urea, bis(methyldiethoxysilylpropyl)amine, 2,2-dimethoxy-1,6-diaza-2-silacyclooctane, 3,5-diamino-N-(4-(methoxydimethylsilyl)phenyl)benzamide, 3,5-diamino-N-(4-(triethoxysilyl)phenyl)benzamide, 5-(ethoxydimethylsilyl)benzene-1,3-diamine, and hydrolysates thereof.

The above-described amino group-containing silane coupling agents may be used singly, or in combination of two or more kinds thereof. Further, the amino group-containing silane coupling agents may be used in combination with a silane coupling agent that does not contain an amino group. For example, a mercapto group-containing silane coupling agent may be used for the purpose of improving the adhesion with a metal.

A polymer (siloxane polymer) formed from any of these silane coupling agents via a siloxane bond (Si—O—Si) may be used as well. For example, from a hydrolysate of 3-aminopropyltrimethoxysilane, a polymer having a linear siloxane structure, a polymer having a branched siloxane structure, a polymer having a cyclic siloxane structure, a polymer having a cage-like siloxane structure, or the like can be obtained. The cage-like siloxane structure is represented by, for example, the following Formula (A-1).

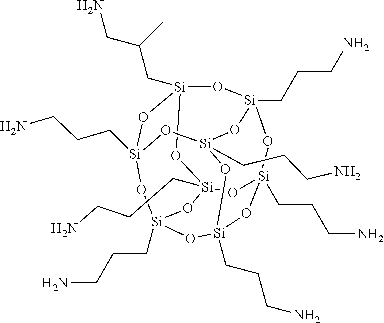 [SMILES: CC(CN)C[Si]12O[Si]3(CCCN)O[Si]4(CCCN)O[Si]5(CCCN)O[Si](CCCN)(O3)O[Si](CCCN)(O[Si](CCCN)(O5)O[Si](CCCN)(O4)O1)O2]

Examples of the siloxanediamines include compounds represented by the following Formula (A-2). In Formula (A-2), i represents an integer from 0 to 4, j represents an integer from 1 to 3, and Me represents a methyl group.

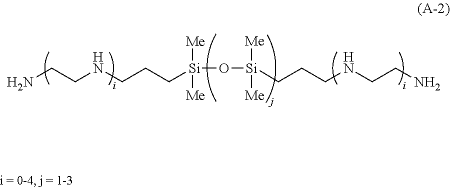

Examples of the siloxanediamines include 1,3-bis(3-aminopropyl)tetramethyldisiloxane (in Formula (A-2), i=0 and j=1) and 1,3-bis(2-aminoethylamino) propyltetramethyldisiloxane (in Formula (A-2), i=1 and j=1).

Examples of the compound (A) also include amine compounds having a ring structure.

Thereamong, those amine compounds that have a ring structure and a weight-average molecular weight of from 90 to 600 are preferred. Examples of the amine compounds that have a ring structure and a weight-average molecular weight of from 90 to 600 include alicyclic amines, aromatic amines, and heterocyclic amines. These amine compounds may each have plural ring structures in the molecule, and the plural ring structures may be the same or different. The amine compounds having a ring structure are more preferably compounds having an aromatic ring since they are likely to provide thermally more stable compounds.

Further, the amine compounds that have a ring structure and a weight-average molecular weight of from 90 to 600 are preferably compounds having a primary amino group since they easily form a thermally crosslinked structure, such as amide, amideimide, or imide, together with the crosslinking agent (B), and can thus improve the heat resistance. Moreover, the above-described amine compounds are preferably diamine compounds having two primary amino groups, triamine compounds having three primary amino groups, or the like since they easily increase the number of thermally crosslinked structures, such as amide, amideimide, and imide, together with the crosslinking agent (B), and can thus further improve the heat resistance.

Examples of the alicyclic amines include cyclohexylamine and dimethylaminocyclohexane.

Examples of the aromatic amines include diaminodiphenyl ether, xylenediamine (preferably p-xylenediamine), diaminobenzene, diaminotoluene, methylenedianiline, dimethyldiaminobiphenyl, bis(trifluoromethyl)diaminobiphenyl, diaminobenzophenone, diaminobenzanilide, bis(aminophenyl) fluorene, bis(aminophenoxy)benzene, bis(aminophenoxy) biphenyl, dicarboxydiaminodiphenylmethane, diaminoresorcin, dihydroxybenzidine, diaminobenzidine, 1,3,5-triaminophenoxybenzene, 2,2′-dimethylbenzidine, tris(4-aminophenyl)amine, 2,7-diaminofluorene, 1,9-diaminofluorene, and dibenzylamine.

Examples of the heterocycles of the heterocyclic amines include heterocycles containing a sulfur atom as a heteroatom (e.g., a thiophene ring), and heterocycles containing a nitrogen atom as a heteroatom (e.g., 5-membered rings, such as a pyrrole ring, a pyrrolidine ring, a pyrazole ring, an imidazole ring, and a triazole ring; 6-membered rings, such as an isocyanuric ring, a pyridine ring, a pyridazine ring, a pyrimidine ring, a pyrazine ring, a piperidine ring, a piperazine ring, and a triazine ring; and condensed rings, such as an indole ring, an indoline ring, a quinoline ring, an acridine ring, a naphthyridine ring, a quinazoline ring, a purine ring, and a quinoxaline ring).

Examples of a heterocyclic amine having a nitrogen-containing heterocycle include melamine, ammeline, melam, melem, and tris(4-aminophenyl)amine.

Examples of an amine compound having both a heterocycle and an aromatic ring include N2,N4,N6-tris(4-aminophenyl)-1,3,5-triazine-2,4,6-triamine.

Since the compound (A) has a primary or secondary amino group, the compound (A) can strongly bond the first and the second substrates to each other by electrostatically interacting with the functional groups such as hydroxy groups, epoxy groups, carboxy groups, amino groups, and mercapto groups that may exist on the surfaces of the first and the second substrates, or by densely forming covalent bonds with the functional groups.

Further, since the compound (A) has a primary or secondary amino group, the compound (A) readily dissolves in the below-described polar solvent (D). By using the compound (A) that readily dissolves in the polar solvent (D), the affinity thereof with the hydrophilic surface of a substrate such as a silicon substrate is increased, so that a smooth film is likely to be formed, and the thickness of a part to be hybrid-bonded can be reduced.

As described above, the compound (A) has a cationic functional group containing at least one of a primary nitrogen atom or a secondary nitrogen atom. When the compound (A) contains a primary nitrogen atom, the ratio of the primary nitrogen atom in all nitrogen atoms in the compound (A) is preferably 20% by mole or more, more preferably 25% by mole or more, still more preferably 30% by mole or more. The compound (A) may have a cationic functional group that contains a primary nitrogen atom but does not contain a nitrogen atom other than the primary nitrogen atom (e.g., a secondary nitrogen atom or a tertiary nitrogen atom).

When the compound (A) contains a secondary nitrogen atom, the ratio of the secondary nitrogen atom in all nitrogen atoms in the compound (A) is preferably from 5% by mole to 50% by mole, more preferably from 10% by mole to 45% by mole.

The compound (A) may also contain a tertiary nitrogen atom in addition to a primary nitrogen atom and a secondary nitrogen atom and, when the compound (A) contains a tertiary nitrogen atom, the ratio of the tertiary nitrogen atom in all nitrogen atoms in the compound (A) is preferably from 20% by mole to 50% by mole, more preferably from 25% by mole to 45% by mole.

In the disclosure, the content of a component derived from the compound (A) in a bonded part is not particularly limited and may be, for example, from 1% by mass to 82% by mass with respect to the whole bonded part, and it is preferably from 5% by mass to 82% by mass, more preferably from 13% by mass to 82% by mass.

### —Crosslinking Agent (B)—

The crosslinking agent (B) is a compound which contains three or more —C(═O)OX groups (wherein, X represents a hydrogen atom or an alkyl group having from 1 to 6 carbon atoms) in the molecule and has a weight-average molecular weight of from 200 to 600, and in which one to six of the three or more —C(═O)OX groups (hereinafter, also referred to as “COOX”) are —C(═O)OH groups (hereinafter, also referred to as “COOH”).

The crosslinking agent (B) is a compound having three or more —C(═O)OX groups (wherein, X represents a hydrogen atom or an alkyl group having from 1 to 6 carbon atoms) in the molecule, preferably a compound having from three to six —C(═O)OX groups in the molecule, more preferably a compound having three or four —C(═O)OX groups in the molecule.

In the crosslinking agent (B), examples of X in each —C(═O)OX group include a hydrogen atom and alkyl groups having from 1 to 6 carbon atoms, among which a hydrogen atom, a methyl group, an ethyl group, and a propyl group are preferred. It is noted here that Xs in the —C(═O)OX groups may be the same or different from each other.

The crosslinking agent (B) is a compound having from one to six —C(═O)OH groups (wherein, the above-described X is a hydrogen atom) in the molecule, preferably a compound having from one to four —C(═O)OH groups in the molecule, more preferably a compound having from two to four —C(═O)OH groups in the molecule, still more preferably a compound having two or three —C(═O)OH groups in the molecule.

The crosslinking agent (B) is a compound having a weight-average molecular weight of from 200 to 600, preferably a compound having a weight-average molecular weight of from 200 to 400.

The crosslinking agent (B) preferably has a ring structure in the molecule. The ring structure may be, for example, an alicyclic structure or an aromatic ring structure. The crosslinking agent (B) may have plural ring structures in the molecule, and the plural ring structures may be the same or different.

Examples of the alicyclic structure include alicyclic structures having from 3 to 8 carbon atoms, preferably alicyclic structures having from 4 to 6 carbon atoms, in which the ring structures may be saturated or unsaturated. More specific examples of the alicyclic structure include: saturated alicyclic structures, such as a cyclopropane ring, a cyclobutane ring, a cyclopentane ring, a cyclohexane ring, a cycloheptane ring, and a cyclooctane ring; and unsaturated alicyclic structures, such as a cyclopropene ring, a cyclobutene ring, a cyclopentene ring, a cyclohexene ring, a cycloheptene ring, and a cyclooctene ring.

The aromatic ring structure is not particularly limited as long as it is a ring structure exhibiting aromaticity, and examples thereof include: benzene aromatic rings, such as a benzene ring, a naphthalene ring, an anthracene ring, and a perylene ring; aromatic heterocyclic rings, such as a pyridine ring and a thiophene ring; and non-benzene aromatic rings, such as an indene ring and an azulene ring.

The ring structure contained in the molecule of the crosslinking agent (B) is preferably, for example, at least one selected from the group consisting of a cyclobutane ring, a cyclopentane ring, a cyclohexane ring, a benzene ring, and a naphthalene ring and, from the standpoint of further improving the heat resistance of the bonded part, at least one of a benzene ring or a naphthalene ring is more preferred.

As described above, the crosslinking agent (B) may have plural ring structures in the molecule and, when the ring structures are benzene, the crosslinking agent (B) may have a biphenyl structure, a benzophenone structure, a diphenyl ether structure, or the like.

The crosslinking agent (B) preferably has a fluorine atom in the molecule, more preferably has from 1 to 6 fluorine atoms in the molecule, still more preferably has from 3 to 6 fluorine atoms in the molecule. For example, the crosslinking agent (B) may have a fluoroalkyl group, specifically a trifluoroalkyl group or a hexafluoroisopropyl group, in the molecule.

Examples of the crosslinking agent (B) include: carboxylic acid compounds, such as alicyclic carboxylic acids, benzene carboxylic acids, naphthalene carboxylic acids, diphthalic acids, and fluorinated aromatic carboxylic acids; and carboxylic acid ester compounds, such as alicyclic carboxylic acid esters, benzene carboxylic acid esters, naphthalene carboxylic acid esters, diphthalic acid esters, and fluorinated aromatic carboxylic acid esters. The carboxylic acid ester compounds are compounds which have a carboxy group (—C(═O)OH group) in the molecule, and in which at least one X in the three or more —C(═O)OX groups is an alkyl group having from 1 to 6 carbon atoms (i.e., the compounds have an ester bond). In the disclosure, when the crosslinking agent (B) is a carboxylic acid ester compound, the aggregation caused by association of the compound (A) and the crosslinking agent (B) is inhibited, and the amount of aggregates and pits is thus reduced, so that the film thickness can be easily adjusted.

The above-described carboxylic acid compounds are preferably tetravalent or lower valent carboxylic acid compounds containing four or less —C(═O)OH groups, more preferably trivalent or tetravalent carboxylic acid compounds containing three or four —C(═O)OH groups.

The above-described carboxylic acid ester compounds are preferably compounds containing three or less carboxy groups (—C(═O)OH groups) and three or less ester bonds in the molecule, more preferably compounds containing two or less carboxy groups and two or less ester bonds in the molecule.

In the carboxylic acid ester compounds, when Xs in the three or more —C(═O)OX groups are alkyl groups having from 1 to 6 carbon atoms, Xs are each preferably a methyl group, an ethyl group, a propyl group, a butyl group, or the like and, from the standpoint of further inhibiting the aggregation caused by association of the compound (A) and the crosslinking agent (B), Xs are each preferably an ethyl group or a propyl group.

Specific examples of the carboxylic acid compounds include, but not limited to: alicyclic carboxylic acids, such as 1,2,3,4-cyclobutanetetracarboxylic acid, 1,2,3,4-cyclopentanetetracarboxylic acid, 1,3,5-cyclohexanetricarboxylic acid, 1,2,4-cyclohexanetricarboxylic acid, 1,2,4,5-cyclohexanetetracarboxylic acid, and 1,2,3,4,5,6-cyclohexanehexacarboxylic acid; benzene carboxylic acids, such as 1,2,4-benzenetricarboxylic acid, 1,3,5-benzene tricarboxylic acid, pyromellitic acid, benzenepentacarboxylic acid, and mellitic acid; naphthalene carboxylic acids, such as 1,4,5,8-naphthalenetetracarboxylic acid and 2,3,6,7-naphthalenetetracarboxylic acid; diphthalic acids, such as 3,3′,5,5′-tetracarboxydiphenylmethane, biphenyl-3,3′,5,5′-tetracarboxylic acid, biphenyl-3,4′,5-tricarboxylic acid, biphenyl-3,3′,4,4′-tetracarboxylic acid, benzophenone-3,3′,4,4′-tetracarboxylic acid, 4,4′-oxydiphthalic acid, 3,4′-oxydiphthalic acid, 1,3-bis(phthalic acid)tetramethyldisiloxane, 4,4′-(ethyne-1,2-diyl)diphthalic acid, 4,4′-(1,4-phenylenebis(oxy))diphthalic acid, 4,4′-([1,1′-biphenyl]-4,4′-diylbis(oxy))diphthalic acid, and 4,4′-((oxybis(4,1-phenylene))bis(oxy))diphthalic acid; perylene carboxylic acids, such as perylene-3,4,9,10-tetracarboxylic acid; anthracene carboxylic acids, such as anthracene-2,3,6,7-tetracarboxylic acid; and fluorinated aromatic carboxylic acids, such as 4,4′-(hexafluoroisopropylidene)diphthalic acid, 9,9-bis(trifluoromethyl)-9H-xanthene-2,3,6,7-tetracarboxylic acid, and 1,4-ditrifluoromethyl pyromellitic acid.

Specific examples of the carboxylic acid ester compounds include those compounds described above as specific examples of the carboxylic acid compounds, in which at least one carboxy group is substituted with an ester group. The carboxylic acid ester compounds are, for example, half-esterified compounds represented by the following Formulae (B-1) to (B-5).

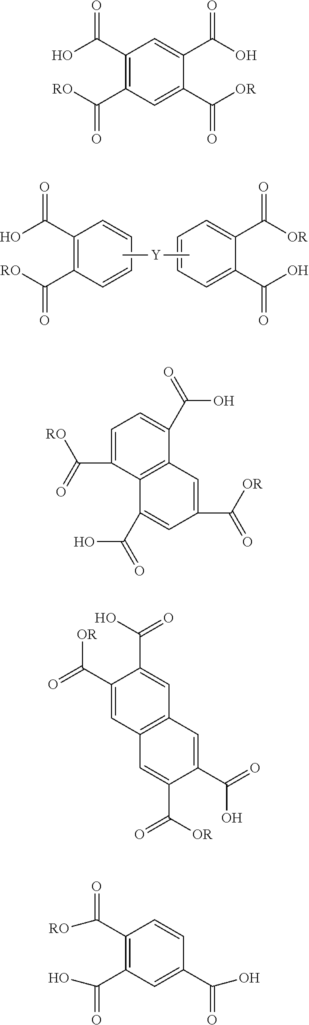

In Formulae (B-1) to (B-5), each of Rs independently represents an alkyl group having from 1 to 6 carbon atoms and, particularly, Rs are each preferably a methyl group, an ethyl group, a propyl group, or a butyl group, more preferably an ethyl group or a propyl group.

In Formula (B-2), Y represents a single bond, O, C═O, or C(CF₃)₂, preferably O.

The half-esterified compounds can be generated by, for example, mixing carboxylic anhydrides that are anhydrides of the above-described carboxylic acid compounds in an alcohol solvent, and ring-opening the carboxylic acid anhydrides.

The content of a component derived from the crosslinking agent (B) in the organic gap fill material is not particularly limited and, for example, a ratio (—(C═O)—Y)/N) of the number of carbonyl groups (—(C—O)—Y) in a substance derived from the crosslinking agent (B) with respect to the number of all nitrogen atoms in a substance derived from the compound (A) is preferably from 0.1 to 3.0, more preferably from 0.3 to 2.5, still more preferably from 0.4 to 2.2. In —(C—O)—Y, Y represents an imide-crosslinked or amide-crosslinked nitrogen atom, OH, or an ester group. When the ratio (—(C═O)—Y)/N is from 0.1 to 3.0, the bonded part suitably has a crosslinked structure such as amide, amideimide, or imide, and exhibits superior heat resistance.

The compound (A) has non-crosslinked cationic functional groups; therefore, when the bonded part contains, as its component, the compound (A) but not the crosslinking agent (B), it is believed that the bonded part has a low crosslinking density and does not exhibit a sufficient heat resistance. On the other hand, the organic gap fill material has a high crosslinking density and exhibit a high heat resistance since the cationic functional groups of the compound (A) and the carboxy groups of the crosslinking agent (B) react with each other and form covalent bonds.

### —Polar Solvent (D)—

Specific examples of the polar solvent (D) include:
protic inorganic compounds, such as water and heavy water;
alcohols, such as methanol, ethanol, 1-propanol, 2-propanol, 1-butanol, 2-butanol, isobutyl alcohol, isopentyl alcohol, cyclohexanol, ethylene glycol, propylene glycol, 2-methoxyethanol, 2-ethoxyethanol, 1-methoxy-2-propanol, benzyl alcohol, diethylene glycol, triethylene glycol, and glycerin;
ethers, such as tetrahydrofuran, dimethoxyethane, 2-methoxy-1-methylethyl acetate (other name: propylene glycol monomethyl ether acetate), and 3-methoxybutyl acetate (other name: methoxybutyl acetate);
aldehydes and ketones, such as furfural, acetone, ethyl methyl ketone, and cyclohexane;
acid derivatives, such as acetic anhydride, ethyl acetate, butyl acetate, ethylene carbonate, propylene carbonate, formaldehyde, N-methylformamide, N,N-dimethylformamide, N-methylacetamide, N,N-dimethylacetamide, N-methyl-2-pyrrolidone, and hexamethylphosphoramide;
nitriles, such as acetonitrile and propionitrile;
nitro compounds, such as nitromethane and nitrobenzene; and
sulfur compounds, such as dimethyl sulfoxide.

The polar solvent (D) preferably contains a protic solvent, more preferably contains water, still more preferably contains ultrapure water.

The content of the polar solvent (D) in a solution is not particularly limited and is, for example, from 1.0% by mass to 99.99896% by mass, preferably from 40% by mass to 99.99896% by mass, with respect to the whole solution.

From the standpoint of volatilizing the polar solvent (D) by heating at the time of forming the organic gap fill material and thereby reducing the amount of residual solvent in the organic gap fill material, the polar solvent (D) has a boiling point of preferably 150° C. or lower, more preferably 120° C. or lower.

### —Additive (C)—

The solution containing a resin material may also contain an additive (C).

Examples of the additive (C) include an acid (C-1) that contains a carboxy group and has a weight-average molecular weight of from 46 to 195, and a base (C-2) that contains a nitrogen atom with no ring structure and has a weight-average molecular weight of from 17 to 120.

The acid (C-1) is an acid that contains a carboxy group and has a weight-average molecular weight of from 46 to 195. It is presumed that, when the acid (C-1) is incorporated as the additive (C), the amino group of the compound (A) and the carboxy group of the acid (C-1) form an ionic bond, and the aggregation caused by association of the compound (A) and the crosslinking agent (B) is thereby inhibited. More specifically, it is presumed that the aggregation is inhibited since the interaction (e.g., electrostatic interaction) between an ammonium ion derived from the amino group of the compound (A) and a carboxylate ion derived from the carboxy group of the acid (C-1) is stronger than the interaction between the ammonium ion derived from the amino group of the compound (A) and a carboxylate ion derived from the carboxy group of the crosslinking agent (B). It is noted here, however, that the present invention is not limited at all by the above presumption.

The acid (C-1) is not particularly limited as long as it contains a carboxy group and has a weight-average molecular weight of from 46 to 195, and examples thereof include monocarboxylic acid compounds, dicarboxylic acid compounds, and oxydicarboxylic acid compounds. More specific examples of the acid (C-1) include formic acid, acetic acid, malonic acid, oxalic acid, citric acid, benzoic acid, lactic acid, glycolic acid, glyceric acid, butyric acid, methoxyacetic acid, ethoxyacetic acid, phthalic acid, terephthalic acid, picolinic acid, salicylic acid, and 3,4,5-trihydroxybenzoic acid.

In the disclosure, the content of the acid (C-1) in the solution containing a resin material is not particularly limited and, for example, a ratio (COOH/N) of the number of carboxy groups in the acid (C-1) with respect to the number of all nitrogen atoms in the compound (A) is preferably from 0.01 to 10, more preferably from 0.02 to 6, still more preferably from 0.5 to 3.

The base (C-2) is a base that contains a nitrogen atom and has a weight-average molecular weight of from 17 to 120. It is presumed that, when the solution containing a resin material contains the base (C-2) as the additive (C), the carboxy group of the crosslinking agent (B) and the amino group of the base (C-2) form an ionic bond, and the aggregation caused by association of the compound (A) and the crosslinking agent (B) is thereby inhibited. More specifically, it is presumed that the aggregation is inhibited since the interaction between a carboxylate ion derived from the carboxy group of the crosslinking agent (B) and an ammonium ion derived from the amino group of the base (C-2) is stronger than the interaction between an ammonium ion derived from the amino group of the compound (A) and the carboxylate ion derived from the carboxy group of the crosslinking agent (B). It is noted here, however, that the invention is not limited at all by the above presumption.

The base (C-2) is not particularly limited as long as it contains a nitrogen atom with no ring structure and has a weight-average molecular weight of from 17 to 120, and examples thereof include monoamine compounds and diamine compounds. More specific examples of the base (C-2) include ammonia, ethylamine, ethanolamine, diethylamine, triethylamine, ethylenediamine, N-acetylethylenediamine, N-(2-aminoethyl) ethanolamine, and N-(2-aminoethyl)glycine.

In the disclosure, the content of the base (C-2) in the solution containing a resin material is not particularly limited and, for example, a ratio (N/COOH) of the number of nitrogen atoms in the base (C-2) with respect to the number of carboxy groups in the crosslinking agent (B) is preferably from 0.5 to 5, more preferably from 0.9 to 3.

In the solution containing a resin material, for the purpose of improving the insulating property or the mechanical strength, tetraethoxysilane, tetramethoxysilane, bis-triethoxysilylethane, bis-triethoxysilylmethane, bis(methyldiethoxysilyl) ethane, 1,1,3,3,5,5-hexaethoxy-1,3,5-trisilacyclohexane, 1,3,5,7-tetramethyl-1,3,5,7-tetrahydroxylcyclosiloxane, 1,1,4,4-tetramethyl-1,4-diethoxydisylethylene, or 1,3,5-trimethyl-1,3,5-trimethyl-1,3,5-triethoxy-1,3,5-trisilacyclohexane may be incorporated.

Further, for the purpose of improving the hydrophobicity of the organic gap fill material, methyltriethoxysilane, dimethyldiethoxysilane, trimethylethoxysilane, or the like may be incorporated. These compounds may also be incorporated for the purpose of controlling the etching selectivity.

The solution containing a resin material may also contain a solvent other than the polar solvent (D), and examples thereof include n-hexane.

Further, the solution containing a resin material may contain, for example, phthalic acid, benzoic acid, or a derivative thereof, for the purpose of improving the electrical characteristics.

Moreover, the solution containing a resin material may contain, for example, benzotriazole or a derivative thereof for the purpose of inhibiting the corrosion of copper.

The pH of the solution containing a resin material is not particularly limited, and it is preferably from 2.0 to 12.0.

When the acid (C-1) is used as the additive (C), it is preferred to mix a mixture of the acid (C-1) and the compound (A) with the crosslinking agent (B). In other words, it is preferred to mix the compound (A) and the acid (C-1) in advance before mixing the compound (A) and the crosslinking agent (B). By this, when the compound (A) and the crosslinking agent (B) are mixed, a solution containing a resin layer forming material can be suitably prevented from being turbid and gelled (gelation may lead to an increase in the time required for making the resulting composition transparent and is thus not preferred).

When the base (C-2) is used as the additive (C), it is preferred to mix a mixture of the base (C-2) and the crosslinking agent (B) with the compound (A). In other words, it is preferred to mix the crosslinking agent (B) and the base (C-2) in advance before mixing the compound (A) and the crosslinking agent (B). By this, when the compound (A) and the crosslinking agent (B) are mixed, a solution containing a resin layer forming material can be suitably prevented from being turbid and gelled (gelation may lead to an increase in the time required for making the resulting composition transparent and is thus not preferred).

The disclosure of Japanese Patent Application No. 2023-075195 filed on Apr. 28, 2023, is hereby incorporated by reference in its entirety.

All the documents, patent applications, and technical standards that are described in the present specification are hereby incorporated by reference to the same extent as if each individual document, patent application, or technical standard is concretely and individually described to be incorporated by reference.

1. A semiconductor structure, comprising:
a composite substrate that comprises two-dimensionally arranged plural silicon dies and an organic gap fill material filled between the plural silicon dies; and
a silicon die that is hybrid-bonded to at least one of the plural silicon dies of the composite substrate, either directly or via another layer.

2. The semiconductor structure according to claim 1, comprising plural composite substrates,
wherein the plural silicon dies of two composite substrates that are adjacent to each other in a stacking direction among the plural composite substrates are hybrid-bonded either directly or via another layer.

3. The semiconductor structure according to claim 2, wherein, among the plural composite substrates, a composite substrate arranged as at least one of outermost layers comprises a through electrode.

4. The semiconductor structure according to claim 2, wherein the plural silicon dies of the two composite substrates that are adjacent to each other in the stacking direction each comprise, on at least a side of a surface to be hybrid-bonded, a silicon die bonding layer that comprises an insulating layer and an electrode.

5. The semiconductor structure according to claim 2, wherein:
the plural silicon dies of the two composite substrates that are adjacent to each other in the stacking direction among the plural composite substrates are hybrid-bonded via a substrate-to-substrate bonding layer provided as the other layer, and
the substrate-to-substrate bonding layer comprises an insulating layer and an electrode.

6. The semiconductor structure according to claim 2, comprising three or more of the composite substrates,
wherein:
among the three or more composite substrates, a composite substrate X that is a composite substrate other than two composite substrates constituting outermost layers comprises a through electrode, and
the plural silicon dies of a composite substrate adjacent to one surface of the composite substrate X and the plural silicon dies of a composite substrate adjacent to another surface of the composite substrate X are electrically connected via the through electrode in the composite substrate X.

7. The semiconductor structure according to claim 2, further comprising a semiconductor substrate that comprises: a semiconductor substrate main body; a semiconductor substrate bonding layer that is arranged on the semiconductor substrate main body and comprises an insulating layer and an electrode; and a through electrode that penetrates through the semiconductor substrate main body,
wherein a semiconductor substrate bonding layer side of the semiconductor substrate is hybrid-bonded with the plural silicon dies of a composite substrate arranged as one of outermost layers among the plural composite substrates.

8. The semiconductor structure according to claim 1, wherein an organic material constituting the organic gap fill material has a glass transition temperature of from 110° C. to 400° C.

9. The semiconductor structure according to claim 1, wherein an organic material constituting the organic gap fill material comprises at least one selected from the group consisting of polyimides, polyamides, polyamideimides, maleimide resins, parylene, polyarylene ethers, polybenzoxazoles, benzocyclobutene resins, epoxy resins, and siloxane bond-containing resins.

10. A method of producing a semiconductor structure, the method comprising the steps of:
preparing two composite substrates that are each temporarily fixed on a temporary fixing substrate and comprise two-dimensionally arranged plural silicon dies and an organic gap fill material filled between the plural silicon dies;
obtaining a laminated body X1 by hybrid-bonding, either directly or via another layer, the plural silicon dies of the two composite substrates that are each temporarily fixed on a temporary fixing substrate;
removing a temporary fixing substrate on one side of the laminated body X1 and thereby exposing a composite substrate on the one side to obtain a laminated body X2; and
removing a temporary fixing substrate on another side of the laminated body X2 to obtain a semiconductor structure.

11. The method of producing a semiconductor structure according to claim 10, satisfying at least one of the following:
in the step of preparing two composite substrates, at least one of the two composite substrates comprises a through electrode; or
after the step of preparing two composite substrates, a through electrode is formed in at least one of the two composite substrates.

12. The method of producing a semiconductor structure according to claim 10, further comprising, before the step of obtaining the laminated body X1, the step of forming a substrate-to-substrate bonding layer on at least one of the two composite substrates, the substrate-to-substrate bonding layer being in contact with the plural silicon dies of the at least one of the two composite substrates and comprising an insulating layer and an electrode,
wherein, in the step of obtaining the laminated body X1, the laminated body X1 is obtained by hybrid-bonding the plural silicon dies of the two composite substrates that are each temporarily fixed on a temporary fixing substrate, via the substrate-to-substrate bonding layer provided as the other layer.

13. The method of producing a semiconductor structure according to claim 10, wherein a temperature of the hybrid-bonding is from 150° C. to 250° C.

14. The method of producing a semiconductor structure according to claim 10, wherein an organic material constituting the organic gap fill material has a glass transition temperature of from 110° C. to 400° C.

15. A method of producing a semiconductor structure, the method comprising the steps of:
preparing a semiconductor substrate comprising a semiconductor substrate main body, a semiconductor substrate bonding layer that is arranged on the semiconductor substrate main body and comprises an insulating layer and an electrode, and a through electrode;
preparing at least two composite substrates that are each temporarily fixed on a temporary fixing substrate and comprise two-dimensionally arranged plural silicon dies and an organic gap fill material filled between the plural silicon dies;
pasting a first composite substrate onto the semiconductor substrate bonding layer of the semiconductor substrate, hybrid-bonding the semiconductor substrate and the plural silicon dies of the first composite substrate, and then peeling off the temporary fixing substrate from the first composite substrate to expose the plural silicon dies; and
where n is defined as an integer of 1 or larger, performing operations of pasting and hybrid-bonding an (n+1)^{th} composite substrate onto an n^{th} composite substrate on the semiconductor substrate bonding layer of the semiconductor substrate either directly or via another layer, and then peeling off the temporary fixing substrate from the (n+1)^{th} composite substrate and thereby exposing the plural silicon dies, the operations being sequentially performed for integers from 1 to n to obtain a semiconductor structure.

16. The method of producing a semiconductor structure according to claim 15, wherein the organic gap fill material comprises at least one selected from the group consisting of polyimides, polyamides, polyamideimides, maleimide resins, parylene, polyarylene ethers, polybenzoxazoles, benzocyclobutene resins, epoxy resins, and siloxane bond-containing resins.

17. The method of producing a semiconductor structure according to claim 15- or 16, wherein at least one of a temperature of hybrid-bonding the semiconductor substrate and the plural silicon dies of the first composite substrate, or a temperature of pasting and hybrid-bonding the (n+1)^{th} composite substrate onto the n^{th} composite substrate either directly or via another layer, is from 150° C. to 250° C.

18. The method of producing a semiconductor structure according to claim 15, satisfying at least one of the following:
in the step of preparing at least two composite substrates, at least one of the at least two composite substrates comprises a through electrode; or
after the step of preparing at least two composite substrates, a through electrode is formed in at least one of the at least two composite substrates.

19. A method of producing a semiconductor structure, the method comprising the steps of:
preparing a semiconductor substrate comprising a semiconductor substrate main body, a semiconductor substrate bonding layer that is arranged on the semiconductor substrate main body and comprises an insulating layer and an electrode, and a through electrode;
two-dimensionally arranging and hybrid-bonding plural silicon dies on the semiconductor substrate bonding layer of the semiconductor substrate, and then filling gaps between the plural silicon dies with an organic gap fill material to form a first composite substrate; and
where n is defined as an integer of 1 or larger, performing operations of two-dimensionally arranging and hybrid-bonding plural silicon dies onto an n^{th} composite substrate on the semiconductor substrate bonding layer of the semiconductor substrate either directly or via another layer, and then filling gaps between the plural silicon dies with an organic gap fill material to form an (n+1)^{th} composite substrate, the operations being sequentially performed for integers from 1 to n to obtain a semiconductor structure.

20. The method of producing a semiconductor structure according to claim 19, satisfying at least one of the following:
the plural silicon dies for the formation of at least one of the first to the (n+1)^{th} composite substrates comprise a through electrode; or
a through electrode is formed in at least one of the first to the (n+1)^{th} composite substrates.
